(19) United States
(12) Patent Application Publication
(10) Pub. No.: US 2024/0172496 A1
(43) Pub. Date: May 23, 2024

(54) DISPLAY APPARATUS

(71) Applicant: SAMSUNG DISPLAY CO., LTD., Yongin-si (KR)

(72) Inventors: Donghee SHIN, Yongin-si (KR); Sunkwun SON, Yongin-si (KR)

(21) Appl. No.: 18/197,370

(22) Filed: May 15, 2023

(30) Foreign Application Priority Data
Nov. 17, 2022 (KR) 10-2022-0154873

(51) Int. Cl. H10K 59/131; H10K 59/121; H10K 59/122

(52) U.S. Cl. CPC H10K 59/131; H10K 59/1213; H10K 59/122

(57) ABSTRACT

A display apparatus includes a substrate, a first semiconductor layer disposed on the substrate and including a first conductive region and a first semiconductor region which are adjacent to each other, a first gate electrode disposed on the first semiconductor layer and at least partially overlapping the first semiconductor region, and a first electrode extending in a first direction and having a first edge at least partially overlapping the first conductive region. A first length, in the first direction, of a first portion of the first conductive region overlapping the first edge of the first electrode is greater than a first width of the first semiconductor region in the first direction.

This application claims priority to Korean Patent Application No. 10-2022-0154873, filed on Nov. 17, 2022, and all the benefits accruing therefrom under 35 U.S.C. § 119, the content of which in its entirety is herein incorporated by reference.

### BACKGROUND

### 1. Field

One or more embodiments relate to a display apparatus.

### 2. Description of the Related Art

Display apparatuses visually display data. Display apparatuses are used as displays of small products, such as mobile phones, or are used as displays of large products, such as televisions.

Display apparatuses include a plurality of pixels that receive electrical signals and emit light to display an image to the outside. Each of the plurality of pixels includes a display element. For example, in the case of organic light-emitting display apparatuses, each pixel includes an organic light-emitting diode (OLED) as a display element. In general, organic light-emitting display apparatuses form thin-film transistors and OLEDs on a substrate, and the OLEDs emit light by themselves.

Applications of display apparatuses have been diversified, and also various design efforts for quality improvement of display apparatuses have been made.

### SUMMARY

Conventionally, such a display apparatus is highly likely to be defective due to an external impact, and it is not easy to display a high-resolution image.

One or more embodiments include a display apparatus capable of displaying a high-resolution image while having a low defect rate due to an external impact.

According to one or more embodiments, a display apparatus includes a substrate, a first semiconductor layer disposed on the substrate and including a first conductive region and a first semiconductor region which are adjacent to each other, a first gate electrode disposed on the first semiconductor layer and at least partially overlapping the first semiconductor region, and a first electrode extending in a first direction and having a first edge at least partially overlapping the first conductive region. In such embodiments, a first length, in the first direction, of a first portion of the first conductive region overlapping the first edge of the first electrode is greater than a first width of the first semiconductor region in the first direction.

In an embodiment, the first semiconductor layer may further include a second conductive region, and the first semiconductor region may be located between the first conductive region and the second conductive region. The first electrode may at least partially overlap the first gate electrode, and further include a second edge which extends in the first direction, at least partially overlaps the second conductive region, and is opposite to the first edge.

In an embodiment, a second length, in the first direction, of a second portion of the second conductive region overlapping the second edge of the first electrode may be greater than the first width of the first semiconductor region in the first direction.

In an embodiment, the first conductive region may include a first protrusion extending in the first direction, and the second conductive region may include a second protrusion extending in the first direction. In such an embodiment, the first edge of the first electrode may at least partially overlap the first protrusion of the first conductive region, and the second edge of the first electrode may at least partially overlap the second protrusion of the second conductive region.

In an embodiment, the display apparatus may include a second electrode interposed between the substrate and the first semiconductor layer and at least partially overlapping the first electrode. In such an embodiment, the first electrode may be disposed on the first gate electrode.

In an embodiment, the first electrode may be in a floating state, and the second electrode may be in a floating state or a state in which a constant voltage is applied thereto.

In an embodiment, the second electrode may have a third edge which extends in the first direction and at least partially overlaps at least one of the first conductive region and the second conductive region. In such an embodiment, a second length, in the first direction, of a second portion of the first semiconductor layer overlapping the third edge of the second electrode may be greater than the first width of the first semiconductor region in the first direction.

In an embodiment, the display apparatus may further include a second semiconductor layer including a different material from the first semiconductor layer and including a second conductive region and a second semiconductor region which are adjacent to each other, a second gate electrode disposed on the second semiconductor layer and at least partially overlapping the second semiconductor region, and a second electrode extending in the first direction and having a second edge at least partially overlapping the second conductive region. In such an embodiment, a second length, in the first direction, of a second portion of the second conductive region overlapping the second edge of the second electrode may be greater than a second width of the second semiconductor region in the first direction.

In an embodiment, the first semiconductor layer may include a silicon semiconductor material, and the second semiconductor layer may include an oxide semiconductor material.

In an embodiment, the display apparatus may further include a pixel circuit disposed on the substrate, and a display element electrically connected to the pixel circuit. In such an embodiment, the pixel circuit may include a driving transistor which controls a current flowing to the display element according to a gate-source voltage, a scan transistor which transmits a data voltage to the driving transistor in response to a scan signal, and a compensating transistor which connects a drain of the driving transistor to a gate of the driving transistor in response to a compensation signal. In such an embodiment, the scan transistor may include the first gate electrode to which the scan signal is applied, and the first semiconductor layer, and the compensating transistor may include the second gate electrode to which the compensation signal is applied, and the second semiconductor layer.

In an embodiment, the first electrode may be disposed in a floating state on the first gate electrode.

In an embodiment, the first electrode may further include a second edge which extends in the first direction, at least partially overlaps the first conductive region, and is opposite to the first edge. In such an embodiment, a second length, in the first direction, of a second portion of the first conductive region overlapping the second edge of the first electrode may be substantially equal to the first length of the first portion of the first conductive region.

In an embodiment, the first conductive region may include a protrusion extending in the first direction, and the first edge and the second edge of the first electrode may at least partially overlap the protrusion of the first conductive region.

In an embodiment, the first electrode may be interposed between the substrate and the first semiconductor layer, and in a state in which a constant voltage is applied thereto.

In an embodiment, in a plan view, the first electrode may be spaced apart from the first semiconductor region of the first semiconductor layer.

According to one or more embodiments, a display apparatus includes a substrate in which a first pixel area and a second pixel area adjacent to each other in a first direction are defined, a conductive layer disposed on the substrate, a first insulating layer disposed on the substrate and having a trench corresponding to a boundary between the first pixel area and the second pixel area, and a pixel separation layer filled in the trench and including a first portion at least partially overlapping the conductive layer and a second portion adjacent to the first portion. In such embodiments, a first length of the first portion of the pixel separation layer in the first direction may be greater than a second length of the second portion of the pixel separation layer in the first direction.

In an embodiment, a first thickness of the first portion of the pixel separation layer in a thickness direction of the substrate may be less than a second thickness of the second portion of the pixel separation layer in the thickness direction of the substrate.

In an embodiment, the conductive layer may be interposed between the substrate and the first portion of the pixel separation layer, and may contact the first portion of the pixel separation layer.

In an embodiment, the pixel separation layer may include a different material from the first insulating layer.

In an embodiment, the first insulating layer may include an inorganic material, and the pixel separation layer may include an organic material.

In an embodiment, the display apparatus may further include a semiconductor layer disposed on the first pixel area and including a conductive region and a semiconductor region which are adjacent to each other. In such an embodiment, the conductive layer may have a first edge extending in a second direction and at least partially overlapping the conductive region, and a third length, in the second direction, of a first portion of the conductive region overlapping the first edge of the conductive layer may be greater than a width of the semiconductor region in the second direction.

In an embodiment, the conductive layer may further include a second edge which extends in the second direction, at least partially overlaps the conductive region, and is opposite to the first edge. In such an embodiment, a fourth length, in the second direction, of a second portion of the conductive region overlapping the second edge of the conductive layer may be substantially equal to the third length of the first portion of the conductive region.

In an embodiment, the conductive region may include a protrusion extending in the second direction, and the first edge and the second edge of the conductive layer may at least partially overlap the protrusion of the conductive region.

In an embodiment, the conductive layer may be interposed between the substrate and the semiconductor layer, and in a state in which a constant voltage is applied.

In an embodiment, in a plan view, the conductive layer may be spaced apart from the semiconductor region of the semiconductor layer.

These and/or other features of embodiments of the invention will become apparent and more readily appreciated from the following description of the embodiments, the claims, and the accompanying drawings.

These general and specific embodiments may be implemented by using a system, a method, a computer program, or a combination thereof.

### BRIEF DESCRIPTION OF THE DRAWINGS

The above and other features of certain embodiments of the disclosure will be more apparent from the following description taken in conjunction with the accompanying drawings, in which:

FIG. 1 is a schematic enlarged plan view of a portion of a display apparatus according to an embodiment;

FIG. 2 is a cross-sectional view of a portion of the display apparatus of FIG. 1 taken along line A-A′;

FIG. 3 is a schematic enlarged plan view of a portion of a display apparatus according to an embodiment;

FIG. 4 is a cross-sectional view of a portion of the display apparatus of FIG. 3 taken along line B-B′;

FIG. 5 is a schematic enlarged plan view of a portion of a display apparatus according to an embodiment;

FIG. 6 is a cross-sectional view of a portion of the display apparatus of FIG. 5 taken along line C-C′;

FIG. 7 is a schematic plan view of a display apparatus according to an embodiment;

FIG. 8 is an equivalent circuit diagram of one pixel included in the display apparatus of FIG. 7;

FIG. 9 is a plan view schematically illustrating respective locations of transistors and capacitors in pixel circuits included in the display apparatus of FIG. 7;

FIGS. 10 through 16 are plan views schematically illustrating, on a layer-by-layer basis, components, such as transistors and capacitors, of the display apparatus illustrated in FIG. 9;

FIG. 17 is a schematic plan view illustrating an insulating layer and a pixel separation layer of a display apparatus according to an embodiment in a plurality of pixels;

FIG. 18 is a cross-sectional view of a portion of FIG. 17 taken along line D-D′;

FIG. 19 is an enlarged plan view schematically illustrating a portion I of FIG. 9;

FIG. 20 is an enlarged plan view schematically illustrating a portion II of FIG. 9;

FIG. 21 is cross-sectional views of a portion of FIG. 19 and a portion of FIG. 20 taken along lines E-E′ and F-F′, respectively;

FIG. 22 is an enlarged plan view schematically illustrating a portion of FIG. 9;

FIG. 23 is an enlarged plan view schematically illustrating a portion of FIG. 9;

FIG. 24 is cross-sectional views of a portion of FIG. 22 and a portion of FIG. 23 taken along lines G-G′ and H-H′, respectively;

FIG. 25 is a schematic plan view of a conductive layer and a semiconductor layer included in a display apparatus according to an embodiment;

FIG. 26 is a schematic plan view of a conductive layer, an insulating layer, and a pixel separation layer included in a display apparatus according to an embodiment; and

FIG. 27 is cross-sectional views of a portion of FIG. 26 taken along lines J-J′ and K-K′, respectively.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. Throughout the disclosure, “A and/or B” represents A or B, or A and B. The expression “at least one of A and B” indicates only A, only B, both A and B, or variations thereof. Throughout the disclosure, the expression “at least one of a, b, or c” or at least one selected from a, b, and c″ indicates only a, only b, only c, both a and b, both a and c, both b and c, all of a, b, and c, or variations thereof.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that when a layer, region, or component is referred to as being “on” another layer, region, or component, it can be directly or indirectly formed on the other layer, region, or component. That is, for example, intervening layers, regions, or components may be present.

Sizes of elements in the drawings may be exaggerated or reduced for convenience of explanation. For example, since sizes and thicknesses of components in the drawings are arbitrarily illustrated for convenience of explanation, embodiments are not limited thereto.

When a certain embodiment may be implemented differently, a specific process order may be performed differently from the described order. For example, two consecutively described processes may be performed substantially at the same time or performed in an order opposite to the described order.

It will also be understood that when a layer, region, or component is referred to as being “connected” or “coupled” to another layer, region, or component, it can be directly connected or coupled to the other layer, region, or/and component or intervening layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present.

In the following examples, the x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another. Herein, x-axis direction (or a direction of the x-axis) may be referred to as x direction, y-axis direction (or a direction of the y-axis) may be referred to as y direction, and z-axis direction (or a direction of the z-axis) may be referred to as z direction.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Hereinafter, embodiments will be described below in more detail with reference to the accompanying drawings. The components or elements that are the same as or are in correspondence with each other are rendered the same reference numeral regardless of the figure number, and any repetitive detailed descriptions thereof are omitted.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

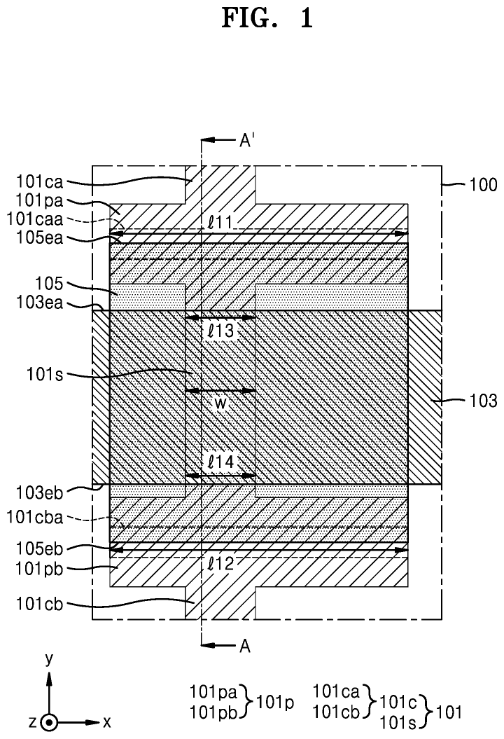

FIG. 1 is a schematic enlarged plan view of a portion of a display apparatus according to an embodiment.

Referring to FIG. 1, an embodiment of the display apparatus may include a substrate 100, a first semiconductor layer 101, a first gate electrode 103, and a first electrode 105.

The substrate 100 may include glass or polymer resin. Examples of the polymer resin may include polyethersulfone, polyacrylate, polyetherimide, polyethylene naphthalate, polyethylene terephthalate, polyphenylene sulfide, polyarylate, polyimide, polycarbonate, and cellulose acetate propionate. The substrate 100 including polymer resin may have flexible, rollable, or bendable characteristics. The substrate 100 may have a multi-layered structure including a layer including the aforementioned polymer resin and an inorganic layer (not shown).

The first semiconductor layer 101 may be located (or disposed) on the substrate 100. The first semiconductor layer 101 may include amorphous silicon or polysilicon. According to an alternative embodiment, the first semiconductor layer 101 may include an oxide of at least one selected from indium (In), gallium (Ga), tin (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). In an embodiment, for example, the first semiconductor layer 101 may be an InSnZnO (ITZO) semiconductor layer, an InGaZnO (IGZO) semiconductor layer, or the like.

The first semiconductor layer 101 may include a conductive region 101c and a semiconductor region 101s. The conductive region 101c and the semiconductor region 101s may be adjacent to each other. In an embodiment, for example, as shown in FIG. 1, the conductive region 101c may include a first conductive region 101ca and a second conductive region 101cb. The semiconductor region 101s may be located between the first conductive region 101ca and the second conductive region 101cb.

According to an embodiment, the conductive region 101c may include a protrusion 101p. In an embodiment, for example, the first conductive region 101ca may include a first protrusion 101pa extending in a first direction (e.g., a ±x direction). The second conductive region 101cb may include a second protrusion 101pb extending in the first direction (e.g., the ±x direction).

The first gate electrode 103 may be located on the first semiconductor layer 101. The first gate electrode 103 may at least partially overlap the first semiconductor layer 101. In an embodiment, for example, the first gate electrode 103 may at least partially overlap the semiconductor region 101s of the first semiconductor layer 101. The first gate electrode 103 may include at least one metal selected from aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W) and copper (Cu), and may have a single-layered or multi-layered structure.

The first electrode 105 may be located on the first gate electrode 103. The first electrode 105 may at least partially overlap the first gate electrode 103 and the first semiconductor layer 101. The first electrode 105 may include at least one metal selected from aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W) and copper (Cu), and may have a single-layered or multi-layered structure.

According to an embodiment, the first electrode 105 may be in a floating state.

According to an embodiment, the first electrode 105 may have an edge (or a side) extending in the first direction (e.g., the ±x direction) and at least partially overlapping the conductive region 101c. In an embodiment, for example, the first electrode 105 may have a first edge 105ea extending in the first direction (e.g., the ±x direction) and at least partially overlapping the first conductive region 101ca, and a second edge 105eb extending in the first direction (e.g., the ±x direction) and at least partially overlapping the second conductive region 101cb. The second edge 105eb of the first electrode 105 may be opposite to the first edge 105ea of the first electrode 105. The first edge 105ea of the first electrode 105 may at least partially overlap the first protrusion 101pa of the first conductive region 101ca. The second edge 105eb of the first electrode 105 may at least partially overlap the second protrusion 101pb of the second conductive region 101cb.

According to an embodiment, a first length l11 of a first portion 101caa of the first conductive region 101ca in the first direction (e.g., the ±x direction) may be greater than a width w of the semiconductor region 101s in the first direction (e.g., the ±x direction). The first portion 101caa of the first conductive region 101ca is a portion that overlaps the first edge 105ea of the first electrode 105 in the first conductive region 101ca. The first portion 101caa of the first conductive region 101ca is a portion corresponding to the first edge 105ea of the first electrode 105.

According to an embodiment, a second length l12 of a second portion 101cba of the second conductive region 101cb in the first direction (e.g., the ±x direction) may be greater than the width w of the semiconductor region 101s in the first direction (e.g., the ±x direction). The second portion 101cba of the second conductive region 101cb is a portion that overlaps the second edge 105eb of the first electrode 105 in the second conductive region 101cb. The second portion 101cba of the second conductive region 101cb is a portion corresponding to the second edge 105eb of the first electrode 105.

According to an embodiment, the first length l11 of the first portion 101caa of the first conductive region 101ca may be greater than a third length l13 of a portion of the first semiconductor layer 101 corresponding to a third edge 103ea of the first gate electrode 103 in the first direction (e.g., the ±x direction). In such an embodiment, the first length l11 of the first portion 101caa of the first conductive region 101ca may be greater than the length l13 of a boundary between the first conductive region 101ca and the semiconductor region 101s. In a plan view, the third edge 103ea of the first gate electrode 103 corresponds to the boundary between the first conductive region 101ca and the semiconductor region 101s.

According to an embodiment, the second length l12 of the second portion 101cba of the second conductive region 101cb may be greater than a fourth length l14 of another portion of the first semiconductor layer 101 corresponding to a fourth edge 103eb of the first gate electrode 103 in the first direction (e.g., the ±x direction). In such an embodiment, the second length l12 of the second portion 101cba of the second conductive region 101cb may be greater than the length l14 of a boundary between the second conductive region 101cb and the semiconductor region 101s. In a plan view, the fourth edge 103eb of the first gate electrode 103 corresponds to the boundary between the second conductive region 101cb and the semiconductor region 101s.

When the display apparatus receives an impact from the outside, a crack may occur in a portion of the first semiconductor layer 101 corresponding to the third and fourth edges 103ea and 103eb of the first gate electrode 103. In an embodiment, the first electrode 105 is disposed to at least partially overlap the first gate electrode 103, such that the portion of the first semiconductor layer 101 corresponding to the third and fourth edges 103ea and 103eb of the first gate electrode 103 may be protected by the first electrode 105. Thus, in such an embodiment, even when the display apparatus receives an impact from the outside, a crack may be effectively prevented from occurring in the portion of the first semiconductor layer 101 corresponding to the third and fourth edges 103ea and 103eb of the first gate electrode 103. In an embodiment, a crack may occur at a portion of the first semiconductor layer 101 corresponding to the first edge 105ea and the second edge 105eb of the first electrode 105 due to an external impact. In such an embodiment, the first semiconductor layer 101 includes the protrusion 101p as shown in FIG. 1, such that the area of the first semiconductor layer 101 corresponding to the first edge 105ea and the second edge 105eb of the first electrode 105 may increase, and thus such cracking may be effectively prevented.

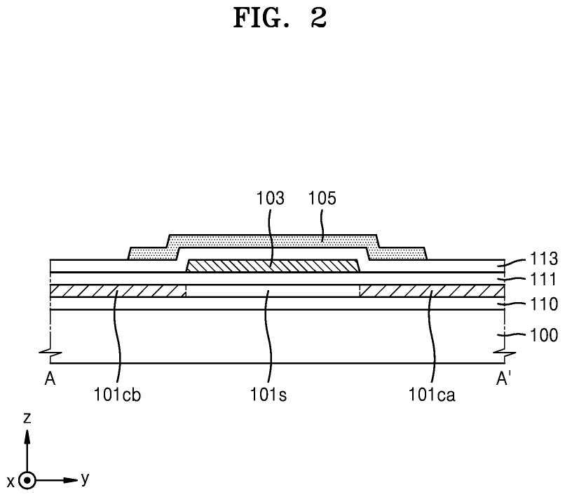

FIG. 2 is a cross-sectional view of a portion of the display apparatus of FIG. 1 taken along line A-A′. The same reference numerals in FIGS. 1 and 2 denote the same elements, and any repetitive detailed descriptions thereof are omitted or simplified.

Referring to FIG. 2, an embodiment of the display apparatus may include a substrate 100, a buffer layer 110, a first semiconductor layer 101, a first gate insulating layer 111, a first gate electrode 103, a second gate insulating layer 113, and a first electrode 105.

The buffer layer 110 may be arranged (or disposed) on the substrate 100. The buffer layer 110 may prevent diffusion of impurity ions and infiltration of moisture or external air, and may provide a planarized surface. A barrier layer (not shown) may be further included (or disposed) between the substrate 100 and the buffer layer 110. The barrier layer may prevent or minimize infiltration of impurities from the substrate 100 and the like into the first semiconductor layer 101. The barrier layer may include an inorganic material (such as oxide or nitride), an organic material, or an organic and inorganic compound, and may be formed as (or defined by) a single layer or multiple layers of an inorganic material and an organic material.

The first semiconductor layer 101 may be disposed on the buffer layer 110. As described above with reference to FIG. 1, the first semiconductor layer 101 may include the semiconductor region 101s and the conductive region 101c. The semiconductor region 101s may be located between the first conductive region 101ca and the second conductive region 101cb.

The first gate insulating layer 111 may be disposed on the first semiconductor layer 101. The first gate insulating layer 111 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO₂), or the like.

The first gate electrode 103 may be disposed on the first gate insulating layer 111. As described above with reference to FIG. 1, the first gate electrode 103 may overlap the semiconductor region 101s of the first semiconductor layer 101.

The second gate insulating layer 113 covering the first gate electrode 103 may be disposed on the first gate insulating layer 111. The second gate insulating layer 113 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO₂), or the like.

The first electrode 105 may be disposed on the second gate insulating layer 113. As described above with reference to FIG. 1, the first electrode 105 may at least partially overlap the first semiconductor layer 101 and the first gate electrode 103.

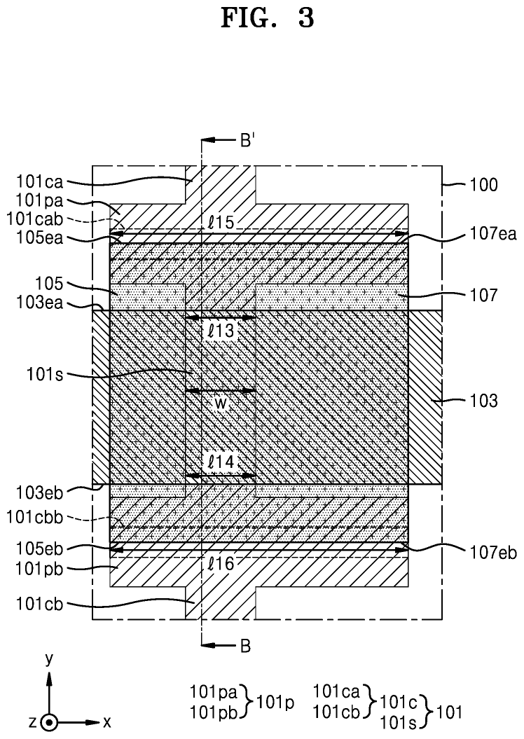

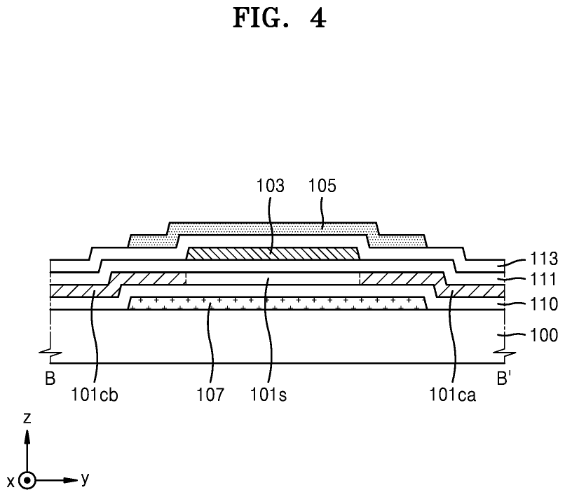

FIG. 3 is a schematic enlarged plan view of a portion of a display apparatus according to an embodiment, and FIG. 4 is a cross-sectional view of a portion of the display apparatus of FIG. 3 taken along line B-B′. FIGS. 3 and 4 correspond to a modification of FIGS. 1 and 2, and thus the display apparatus shown in FIGS. 3 and 4 is substantially the same as the display apparatus shown in FIGS. 1 and 2 except for the structure of an electrode. Hereinafter, any repetitive detailed description of the same or like elements in FIGS. 3 and 4 as those described above with reference to FIGS. 1 and 2 will be omitted, and the differences will be mainly described.

Referring to FIG. 3, an embodiment of the display apparatus may further include a second electrode 107. The second electrode 107 may at least partially overlap the first gate electrode 103, the first semiconductor layer 101, and the first electrode 105. The second electrode 107 may include at least one metal selected from aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W) and copper (Cu), and may have a single-layered or multi-layered structure.

According to an embodiment, as shown in FIG. 4, the second electrode 107 may be interposed between the substrate 100 and the first semiconductor layer 101. The second electrode 107 may be interposed between the substrate 100 and the buffer layer 110.

According to an embodiment, the second electrode 107 may be in a floating state or in a state in which a constant voltage is applied thereto.

According to an embodiment, the second electrode 107 may have an edge (or a side) extending in the first direction (e.g., the ±x direction) and at least partially overlapping the conductive region 101c. In an embodiment, for example, the second electrode 107 may have a fifth edge 107ea extending in the first direction (e.g., the ±x direction) and at least partially overlapping the first conductive region 101ca, and a sixth edge 107eb extending in the first direction (e.g., the ±x direction) and at least partially overlapping the second conductive region 101cb. The sixth edge 107eb of the second electrode 107 may be opposite to the fifth edge 107ea of the second electrode 107. The fifth edge 107ea of the second electrode 107 may at least partially overlap the first protrusion 101pa of the first conductive region 101ca. The sixth edge 107eb of the second electrode 107 may at least partially overlap the second protrusion 101pb of the second conductive region 101cb.

According to an embodiment, a fifth length l15 of a third portion 101cab of the first conductive region 101ca in the first direction (e.g., the ±x direction) may be greater than the width w of the semiconductor region 101s in the first direction (e.g., the ±x direction). The third portion 101cab of the first conductive region 101ca is a portion that overlaps the fifth edge 107ea of the second electrode 107 in the first conductive region 101ca. The third portion 101cab of the first conductive region 101ca is a portion corresponding to the fifth edge 107ea of the second electrode 107.

According to an embodiment, a sixth length l16 of a fourth portion 101cbb of the second conductive region 101cb in the first direction (e.g., the ±x direction) may be greater than the width w of the semiconductor region 101s in the first direction (e.g., the ±x direction). The fourth portion 101cbb of the second conductive region 101cb is a portion that overlaps the sixth edge 107eb of the second electrode 107 in the second conductive region 101cb. The fourth portion 101cbb of the second conductive region 101cb is a portion corresponding to the sixth edge 107eb of the second electrode 107.

According to an embodiment, the first length l15 of the third portion 101cab of the first conductive region 101ca may be greater than the third length l13 of the portion of the first semiconductor layer 101 corresponding to the third edge 103ea of the first gate electrode 103 in the first direction (e.g., the ±x direction). In such an embodiment, the fifth length l15 of the third portion 101cab of the first conductive region 101ca may be greater than the length l13 of the boundary between the first conductive region 101ca and the semiconductor region 101s.

According to an embodiment, the sixth length l16 of the fourth portion 101cbb of the second conductive region 101cb may be greater than the fourth length l14 of the other portion of the first semiconductor layer 101 corresponding to the fourth edge 103eb of the first gate electrode 103 in the first direction (e.g., the ±x direction). In such an embodiment, the sixth length l16 of the fourth portion 101cbb of the second conductive region 101cb may be greater than the length l14 of the boundary between the second conductive region 101cb and the semiconductor region 101s.

In such an embodiment, the first electrode 105 is disposed over the first gate electrode 103 and the second electrode 107 is disposed under the first gate electrode 103, such that the portion of the first semiconductor layer 101 corresponding to the third and fourth edges 103ea and 103eb of the first gate electrode 103 may be protected by the first and second electrodes 105 and 107. Thus, even when the display apparatus receives an impact from the outside, a crack may be effectively prevented from occurring in the portion of the first semiconductor layer 101 corresponding to the third and fourth edges 103ea and 103eb of the first gate electrode 103. In an embodiment, a crack may occur at a portion of the first semiconductor layer 101 corresponding to the fifth edge 107ea and the sixth edge 107eb of the second electrode 107 due to an external impact. In an embodiment, the first semiconductor layer 101 includes the protrusion 101p as shown in FIG. 3, such that the area of the first semiconductor layer 101 corresponding to the fifth edge 107ea and the sixth edge 107eb of the second electrode 107 may increase, and thus such cracking may be effectively prevented.

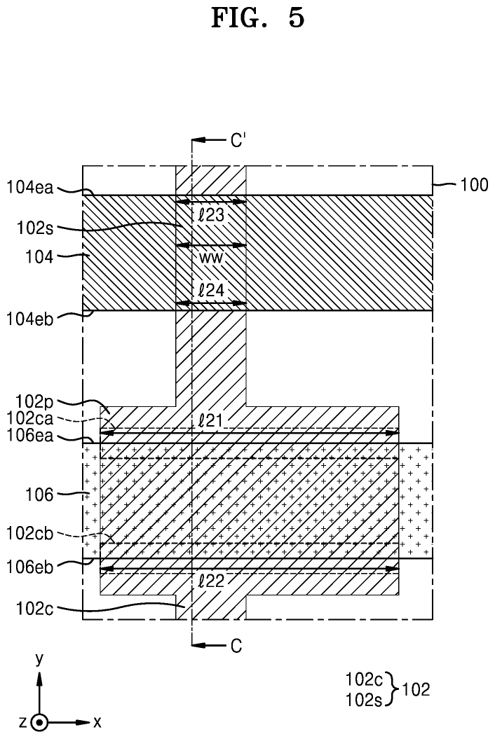

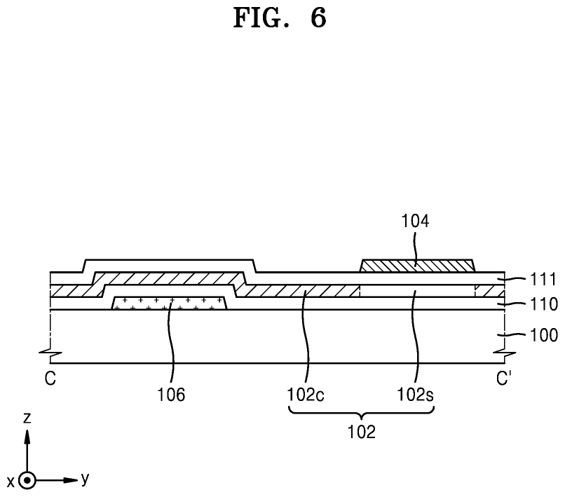

FIG. 5 is a schematic enlarged plan view of a portion of a display apparatus according to an embodiment, and FIG. 6 is a cross-sectional view of a portion of the display apparatus of FIG. 5 taken along line C-C′.

Referring to FIG. 5, an embodiment of the display apparatus may include a substrate 100, a second semiconductor layer 102, a second gate electrode 104, and a third electrode 106.

The second semiconductor layer 102 may be disposed on the buffer layer 110 arranged on the substrate 100. The second semiconductor layer 102 may include a conductive region 102c and a semiconductor region 102s adjacent to each other. The second semiconductor layer 102 may include amorphous silicon or polysilicon. According to an alternative embodiment, the second semiconductor layer 102 may include an oxide of at least one selected from indium (In), gallium (Ga), tin (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). In an embodiment, for example, the second semiconductor layer 102 may be an InSnZnO (ITZO) semiconductor layer, an InGaZnO (IGZO) semiconductor layer, or the like.

According to an embodiment, the conductive region 102c may include a protrusion 102p. The protrusion 102p of the conductive region 102c may extend in the first direction (e.g., the ±x direction).

The second electrode 104 may be arranged on the first gate insulating layer 111 disposed on the second semiconductor layer 102. The second gate electrode 104 may at least partially overlap the second semiconductor layer 102. In an embodiment, for example, the second gate electrode 104 may at least partially overlap the semiconductor region 102s of the second semiconductor layer 102. The second gate electrode 104 may include at least one metal selected from aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W) and copper (Cu), and may have a single-layered or multi-layered structure.

The third electrode 106 may be interposed between the substrate 100 and the buffer layer 110. The third electrode 106 may at least partially overlap the second semiconductor layer 102. In an embodiment, for example, the third electrode 106 may at least partially overlap the conductive region 102c of the second semiconductor layer 102. In a plan view or when viewed in the z direction (i.e., a thickness direction of the substrate 100), the third electrode 106 may be spaced apart from the semiconductor region 102s of the second semiconductor layer 102. The third electrode 106 may include at least one metal selected from aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W) and copper (Cu), and may have a single-layered or multi-layered structure.

According to an embodiment, the third electrode 106 may be in a state in which a constant voltage is applied thereto.

According to an embodiment, the third electrode 106 may have an edge (or a side) extending in the first direction (e.g., the ±x direction) and at least partially overlapping the conductive region 102c. In an embodiment, for example, the third electrode 106 may have a first edge 106ea extending in the first direction (e.g., the ±x direction) and at least partially overlapping the conductive region 102c, and a second edge 106eb extending in the first direction (e.g., the ±x direction) and at least partially overlapping the conductive region 102c. The second edge 106eb of the third electrode 106 may be opposite to the first edge 106ea of the third electrode 106. The first edge 106ea and the second edge 106eb of the third electrode 106 may at least partially overlap the protrusion 102p of the conductive region 102c.

According to an embodiment, a first length l21 of a first portion 102ca of the conductive region 102c in the first direction (e.g., the ±x direction) may be greater than a width ww of the semiconductor region 102s in the first direction (e.g., the ±x direction). The first portion 102ca of the conductive region 102c is a portion that overlaps the first edge 106ea of the third electrode 106 in the conductive region 102c. The first portion 102ca of the conductive region 102c corresponds to the first edge 106ea of the third electrode 106.

According to an embodiment, a second length l22 of a second portion 102cb of the conductive region 102c in the first direction (e.g., the ±x direction) may be greater than the width ww of the semiconductor region 102s in the first direction (e.g., the ±x direction). The second portion 102cb of the conductive region 102c is a portion that overlaps the second edge 106eb of the third electrode 106 in the conductive region 102c. The second portion 102cb of the conductive region 102c corresponds to the second edge 106eb of the third electrode 106.

According to an embodiment, the second length l22 of the second portion 102cb of the conductive region 102c may be substantially equal to the first length l21 of the first portion 102ca of the conductive region 102c.

According to an embodiment, the first length l21 of the first portion 102ca of the conductive region 102c may be greater than a third length l23 of a portion of the second semiconductor layer 102 corresponding to a third edge 104ea of the second gate electrode 104 in the first direction (e.g., the ±x direction). In such an embodiment, the first length l21 of the first portion 102ca of the conductive region 102c may be greater than a length l23 of a boundary between the conductive region 102c and the semiconductor region 102s. In a plan view, the third edge 104ea of the second gate electrode 104 corresponds to the boundary between the conductive region 102c and the semiconductor region 102s.

According to an embodiment, the second length l22 of the second portion 102cb of the conductive region 102c may be greater than a fourth length l24 of another portion of the second semiconductor layer 102 corresponding to a fourth edge 104eb of the second gate electrode 104 in the first direction (e.g., the ±x direction). In such an embodiment, the second length l22 of the second portion 102cb of the conductive region 102c may be greater than the length l24 of the boundary between the conductive region 102c and the semiconductor region 102s. In a plan view, the fourth edge 104eb of the second gate electrode 104 corresponds to the boundary between the conductive region 102c and the semiconductor region 102s.

When the display apparatus receives an impact from the outside, a crack may occur in a portion of the second semiconductor layer 102 corresponding to the first and second edges 106ea and 106eb of the third gate electrode 106. In an embodiment, as shown in FIG. 5, the second semiconductor layer 102 includes the protrusion 102p, such that the area of the second semiconductor layer 102 corresponding to the first edge 106ea and the second edge 106eb of the third electrode 106 may be increased, and thus such cracking may be effectively prevented g.

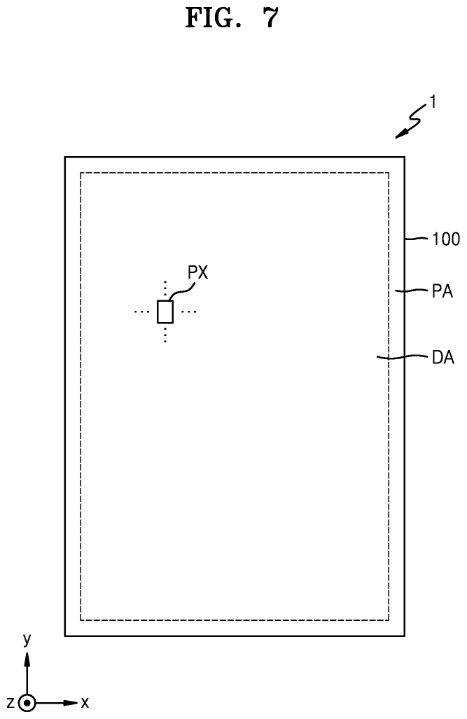

FIG. 7 is a schematic plan view of the display apparatus 1 according to an embodiment.

Referring to FIG. 7, an embodiment of the display apparatus 1 includes a display area DA where an image is displayed, and a peripheral area PA surrounding at least a portion of the display area DA. The display apparatus 1 may provide an image to the outside by using light emitted from the display area DA. Because the display apparatus 1 includes a substrate 100, it may be considered that the substrate 100 has the display area DA and the peripheral area PA. In other words, the display area DA and the peripheral area PA may be defined in the substrate 100.

The substrate 100 may include at least one selected from various materials, such as glass, metal, or plastic. According to an embodiment, the substrate 100 may include a flexible material. The flexible material is referred to as a material that may be easily bent, folded, or rolled. The substrate 100 of the flexible material may include ultra-thin glass, metal, or plastic.

As shown in FIG. 7, the display area DA may have a rectangular shape. According to an alternative embodiment, the display area DA may have a polygonal shape (e.g., a triangular shape, a pentagonal shape, or a hexagonal shape), a circular shape, an elliptical shape, or an irregular shape.

Pixels PX including various display elements such as an organic light-emitting diode (OLED) may be located in the display area DA of the substrate 100. A plurality of pixels PX may be included, and the plurality of pixels PX may be arranged in any of various patterns such as a stripe pattern, a PenTile® pattern, or a mosaic pattern to form an image. Herein, each of the plurality of pixels PX refers to subpixels that emit light beams of different colors from each other, and may be one of, for example, a red subpixel, a green subpixel, and a blue subpixel.

Hereinafter, for convenience of description, embodiments where the display apparatus is an organic light-emitting display will be described in detail, but a display apparatus is not limited thereto. According to an alternative embodiment, the display apparatus of the disclosure may be an inorganic light-emitting display, a quantum dot light-emitting display, or the like. In an embodiment, for example, an emission layer of the display element of the display apparatus may include an organic material, include an inorganic material, include quantum dots, include an organic material and quantum dots, include an inorganic material and quantum dots, or include an organic material, an inorganic material, and quantum dots.

The peripheral area PA of the substrate 100 located around the display area DA may be an area where an image is not displayed. Various wirings for transmitting electric signals to be applied to the display area DA, and pads to which a printed circuit board (PCB) or a driver integrated circuit (IC) chip is attached may be located in the peripheral area PA.

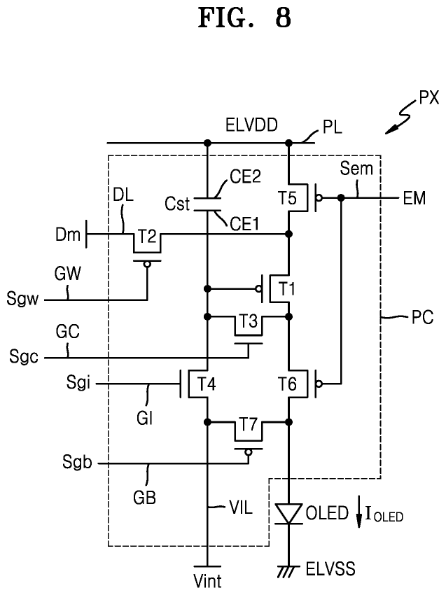

FIG. 8 is an equivalent circuit diagram of a pixel PX included in the display apparatus 1 of FIG. 1.

Referring to FIG. 8, in an embodiment, the pixel PX may include a pixel circuit PC, and a display element electrically connected to the pixel circuit PC. In an embodiment, for example, the display element may be an organic light-emitting diode OLED. A cathode of the display element may be a common electrode to which a common voltage ELVSS is applied.

As illustrated in FIG. 8, the pixel circuit PC may include a plurality of transistors T1 through T7 and a storage capacitor Cst. The plurality of transistors T1 through T7 and the storage capacitor Cst may be connected to signal lines GW, GC, GI, GB, EM, and DL, an initializing voltage line VIL, and a driving voltage line PL. According to some embodiments, at least one selected from the signal lines GW, GC, GI, GB, EM, and DL, the initialization voltage line VIL, and/or the driving voltage line PL may be shared by neighboring pixels PX.

The plurality of transistors T1 through T7 may include a driving transistor T1, a scan transistor T2, a compensating transistor T3, a gate initializing transistor T4, an operation control transistor T5, a light-emission control transistor T6, and an anode initializing transistor T7.

Some of the plurality of transistors T1 through T7 may be n-channel metal-oxide semiconductor (NMOS) transistors, e.g., NMOS field effect transistors (NMOSTFETs), and the others may be p-channel metal-oxide semiconductor (PMOS) transistors, e.g., PMOS field effect transistors (PMOSFETs). In an embodiment, for example, as illustrated in FIG. 8, the compensating transistor T3 and the gate initializing transistor T4 from among the plurality of transistors T1 through T7 may be NMOS transistors, and the rest may be p-channel PMOS transistors.

According to an alternative embodiment, the compensating transistor T3, the gate initializing transistor T4, and the anode initializing transistor T7 among the plurality of transistors T1 through T7 may be NMOS transistors and the others may be PMOS transistors. Alternatively, only one of the plurality of transistors T1 through T7 may be an NMOS transistor, and the others may be PMOS transistors. Alternatively, all of the plurality of transistors T1 through T7 may be NMOS transistors.

The signal lines GW, GC, GI, GB, EM, and DL include a scan line GW that transmits a scan signal Sgw, a compensation gate line GC that transmits a compensation signal Sgc, an initialization gate line GI that transmits an initialization signal Sgi to the gate initializing transistor T4, an emission control line EM that transmits an emission control signal Sem to the operation control transistor T5 and the emission control transistor T6, a next scan line GB that transmits a next scan signal Sgb to the anode initializing transistor T7, and a data line DL that intersects the scan line GW and transmits a data voltage (or data signal) Dm.

The driving voltage line PL transmits a driving voltage ELVDD to the driving transistor T1, and the initialization voltage line VIL transmits an initializing voltage Vint that initializes a gate of the driving transistor T1 and an anode of the display element.

The gate of the driving transistor T1 is connected to the storage capacitor Cst, a source of the driving transistor T1 is connected to the driving voltage line PL via the operation control transistor T5, and a drain of the driving transistor T1 is electrically connected to an anode of the organic light emitting diode OLED via the emission control transistor T6. The driving transistor T1 receives the data signal Dm based on a switching operation of the scan transistor T2 and supplies a driving current IDLED to the organic light-emitting diode OLED.

A gate of the scan transistor T2 is connected to the scan line GW, a source of the scan transistor T2 is connected to the data line DL, and a drain of the scan transistor T2 is connected to the source of the driving transistor T1 and is also connected to the driving voltage line PL via the operation control transistor T5. The scan transistor T2 is turned on in response to the scan signal Sgw received via the scan line GW and performs a switching operation of transmitting the data signal Dm received from the data line DL to the source electrode of the driving thin-film transistor T1.

A gate of the compensating transistor T3 is connected to the compensation gate line GC. A drain of the compensating transistor T3 is connected to the drain of the driving transistor T1 and is also connected to the anode of the organic light-emitting diode OLED via the emission control transistor T6. A source of the compensating transistor T3 is connected to a lower electrode CE1 of the storage capacitor Cst and the gate of the driving transistor T1. The source of the compensating transistor T3 is also connected to a drain of the gate initializing transistor T4. The compensating transistor T3 is turned on in response to the compensation signal Sgc received through the compensation gate line GC to electrically connect the gate and the drain of the driving transistor T1 to each other, thereby diode-connecting the driving transistor T1.

A gate of the gate initializing transistor T4 is connected to the initialization gate line GI. A source of the gate initializing transistor T4 is connected to the drain of the anode initializing transistor T7 and the initialization voltage line VIL. The drain of the gate initializing transistor T4 is connected to the lower electrode CE1 of the storage capacitor Cst, the source of the compensating transistor T3, and the gate of the driving transistor T1. The gate initializing transistor T4 is turned on in response to the initialization signal Sgi received via the initialization gate line GI and performs an initialization operation of transmitting the initializing voltage Vint to the gate of the driving transistor T1 to initialize a voltage of the gate of the driving transistor T1.

A gate of the operation control transistor T5 is connected to the emission control line EM, a source of the operation control transistor T5 is connected to the driving voltage line PL, and a drain of the operation control transistor T5 is connected to the source of the driving transistor T1 and the drain of the scan transistor T2.

A gate of the emission control transistor T6 is connected to the emission control line EM, a source of the emission control transistor T6 is connected to the drain of the driving transistor T1 and the drain of the compensating transistor T3, and a drain of the emission control transistor T6 is electrically connected to a source of the anode initializing transistor T7 and the anode of the organic light emitting diode OLED.

The operation control transistor T5 and the emission control transistor T6 are simultaneously turned on in response to the emission control signal Sem received via the emission control line EM, and thus the driving voltage ELVDD is transmitted to the organic light-emitting diode OLED to allow the driving current IDLED to flow in the organic light-emitting diode OLED.

A gate of the anode initializing transistor T7 is then connected to the next scan line GB, the source of the anode initializing transistor T7 is connected to the drain of the emission control transistor T6 and the anode of the organic light emitting diode OLED, and a drain of the anode initializing transistor T7 is connected to the source of the gate initializing transistor T4 and the initialization voltage line VIL. The anode initializing transistor T7 is turned on in response to the next scan signal Sgb received via the next scan line GB to initialize the anode of the organic light-emitting diode OLED.

In an embodiment, as shown in FIG. 8, the source of the gate initializing transistor T4 and the drain of the anode initializing transistor T7 are connected to a same initialization voltage line VIL. However, according to an alternative embodiment, the source of the gate initializing transistor T4 and the drain of the anode initializing transistor T7 may be connected to different initialization voltage lines, respectively.

In an embodiment, the next scan signal Sgb may be substantially synchronized with the scan signal Sgw. According to an alternative embodiment, the next scan signal Sgb may be substantially synchronized with a scan signal Sgw on a next row. In an embodiment, for example, the next scan line GB may be substantially the same as a scan line GW on a next row. Pixels PXs adjacent to each other in a column direction may share a scan line GW.

In an embodiment, the anode initializing transistor T7 may be connected to the next scan line GB as illustrated in FIG. 8. According to an alternative embodiment, the anode initializing transistor T7 may be connected to the emission control line EM and thus driven according to the emission control signal Sem. The locations of the source and drain of each transistor may be interchanged depending on the type (p-type or n-type) of the transistor.

The storage capacitor Cst may include the lower electrode CE1 and an upper electrode CE2. The lower electrode CE1 of the storage capacitor Cst is connected to the gate of the driving transistor T1, and the upper electrode CE2 of the storage capacitor Cst is connected to the driving voltage line PL. The storage capacitor Cst may store a charge corresponding to a difference between a gate voltage of the driving transistor T1 and the driving voltage ELVDD.

In an alternative embodiment, although not shown in FIG. 8, the pixel circuit PC may further include a boost capacitor including a first electrode and a second electrode. The first electrode of the boost capacitor may be connected to the gate of the scan transistor T2 and the scan line GW, and the second electrode thereof may be connected to the source of the compensating transistor T3.

A detailed operation of each pixel PX according to an embodiment will now be described.

During an initialization period, when the initialization signal Sgi is supplied via the initialization gate line GI, the gate initializing transistor T4 is turned on in response to the initialization signal Sgi, and the driving transistor T1 is initialized by the initializing voltage Vint supplied from the initialization voltage line VIL.

During a data programming period, when the scan signal Sgw and the compensation signal Sgc are supplied through the scan line GW and the compensation gate line GC, the scan transistor T2 and the compensating transistor T3 are turned on in response to the scan signal Sgw and the compensation signal Sgc. At this time, the driving transistor T1 is diode-connected by the turned-on compensating transistor T3 and is biased in a forward direction.

Then, a compensating voltage (Dm+Vth) (where Vth has a negative value) obtained by subtracting a threshold voltage (Vth) of the driving transistor T1 from the data signal Dm supplied from the data line DL is applied to the gate of the driving transistor T1.

The driving voltage ELVDD and the compensating voltage (Dm+Vth) are applied to both ends of the storage capacitor Cst, and a charge corresponding to a voltage difference between opposing ends is stored in the storage capacitor Cst.

During an emission period, the operation control transistor T5 and the emission control transistor T6 are turned on by the emission control signal Sem supplied from the emission control line EM. The driving current IDLED is generated based on a voltage difference between the gate voltage of the driving transistor T1 and the driving voltage ELVDD, and is supplied to the organic light emitting diode OLED through the emission control transistor T6.

According to an embodiment, at least one of the plurality of transistors T1, T2, T3, T4, T5, T6, and T7 includes a semiconductor layer including oxide, and the others thereof include a semiconductor layer including silicon.

In an embodiment, the driving transistor T1 directly affecting the brightness of the display apparatus includes a semiconductor layer including polycrystal silicon having high reliability, and thus a high-resolution display apparatus may be realized.

Because an oxide semiconductor has high carrier mobility and a low leakage current, a voltage drop is not substantial even when a driving time is long. In other words, because a change in the color of an image according to a voltage drop is not substantial even during low frequency driving, low frequency driving is possible.

Because an oxide semiconductor has a small leakage current as described above, at least one of the compensating transistor T3, the gate initializing transistor T4, and the anode initializing transistor T7 connected to the gate of the driving transistor T1 employs an oxide semiconductor, so that flowing of a leakage current to the gate of the driving transistor T1 may be effectively prevented and also power consumption may be reduced.

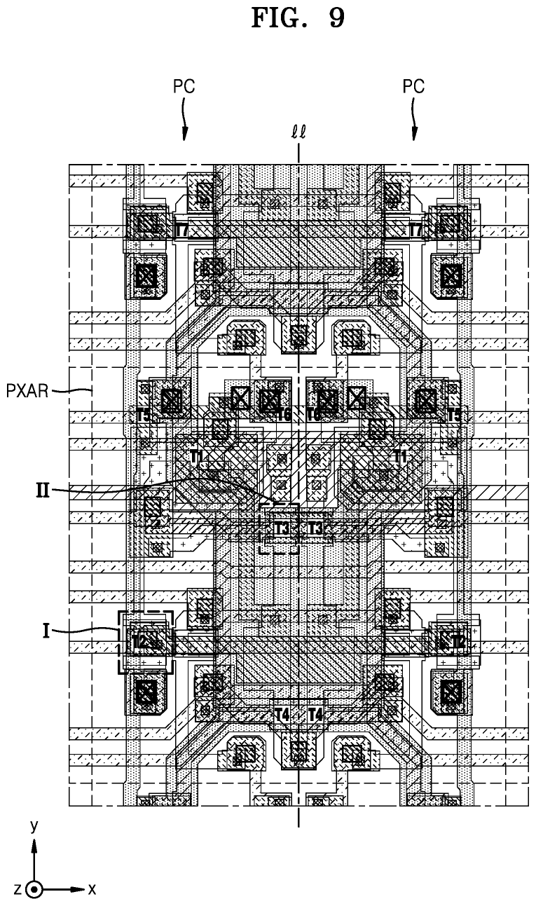

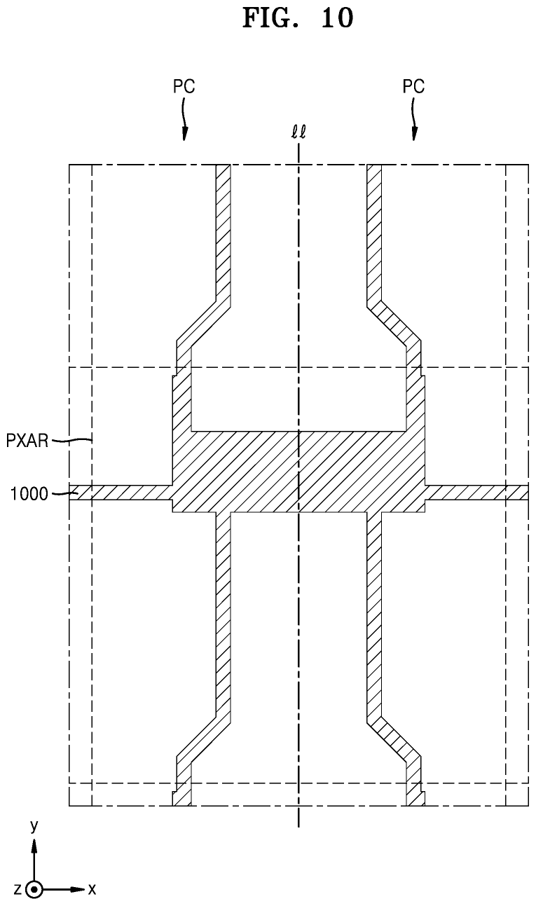

FIG. 9 is a plan view schematically illustrating respective locations of transistors and capacitors in pixel circuits included in the display apparatus 1 of FIG. 7, and FIGS. 10 through 16 are plan views schematically illustrating, on a layer-by-layer basis, components, such as transistors and capacitors, of the display apparatus illustrated in FIG. 9.

First, referring to FIG. 9, the display apparatus 1 of FIG. 7 may include pixel areas PXAR. The display area DA (refer to FIG. 7) of the display apparatus 1 may include the pixel areas PXAR. In other words, the pixel areas PXAR may be defined in the display area DA of the display apparatus 1. Because the display apparatus 1 includes the substrate 100 (see FIG. 7), it may be considered that the substrate 100 includes the pixel areas PXAR or the pixel areas PXAR are defined in the substrate 100. The pixel areas PXAR may be arranged in the first direction (for example, the ±x direction) and a second direction (for example, a ±y direction).

According to an embodiment, the pixel circuit PC may be disposed on two pixel areas PXAR adjacent to each other in the second direction (e.g., ±y direction). In such an embodiment, the pixel circuit PC overlap the two pixel areas PXAR adjacent to each other in the second direction (e.g., ±y direction).

FIG. 9 illustrates an embodiment where pixel circuits PC adjacent to each other are substantially symmetrical to each other about an imaginary line ll. However, according to an alternative embodiment, the pixel circuits PC may have a same structure as each other.

A pixel circuit PC may include a driving transistor T1, a scan transistor T2, a compensating transistor T3, a gate initializing transistor T4, an operation control transistor T5, a light-emission control transistor T6, and an anode initializing transistor T7.

According to an embodiment, the driving transistor T1, the scan transistor T2, the compensating transistor T3, the gate initializing transistor T4, the operation control transistor T5, the light-emission control transistor T6, and the anode initializing transistor T7 may be classified into and arranged in two different pixel areas PXAR. In an embodiment, for example, as illustrated in FIG. 9, the anode initializing transistor T7 may be arranged in a different pixel area PXAR from a pixel area PXAR in which the driving transistor T1, the scan transistor T2, the compensating transistor T3, the gate initializing transistor T4, the operation control transistor T5, and the light-emission control transistor T6 are arranged.

FIG. 9 illustrates an embodiment where the anode initializing transistor T7 is arranged in a pixel area PXAR located on a previous row of the pixel area PXAR in which the driving transistor T1, the scan transistor T2, the compensating transistor T3, the gate initializing transistor T4, the operation control transistor T5, and the light-emission control transistor T6 are arranged. However, according to an alternative embodiment, the anode initializing transistor T7 may be arranged in a pixel area PXAR located on a next row of the pixel area PXAR in which the driving transistor T1, the scan transistor T2, the compensating transistor T3, the gate initializing transistor T4, the operation control transistor T5, and the light-emission control transistor T6 are arranged.

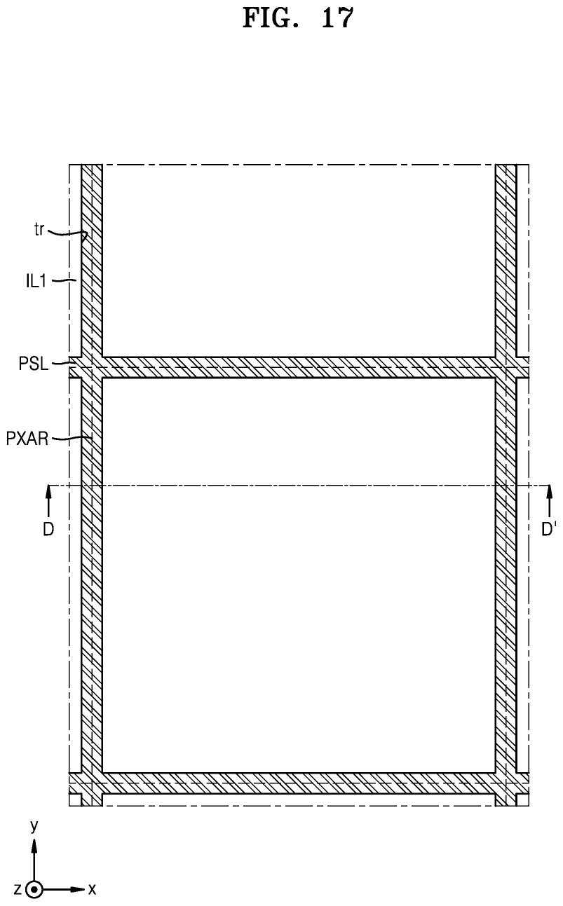

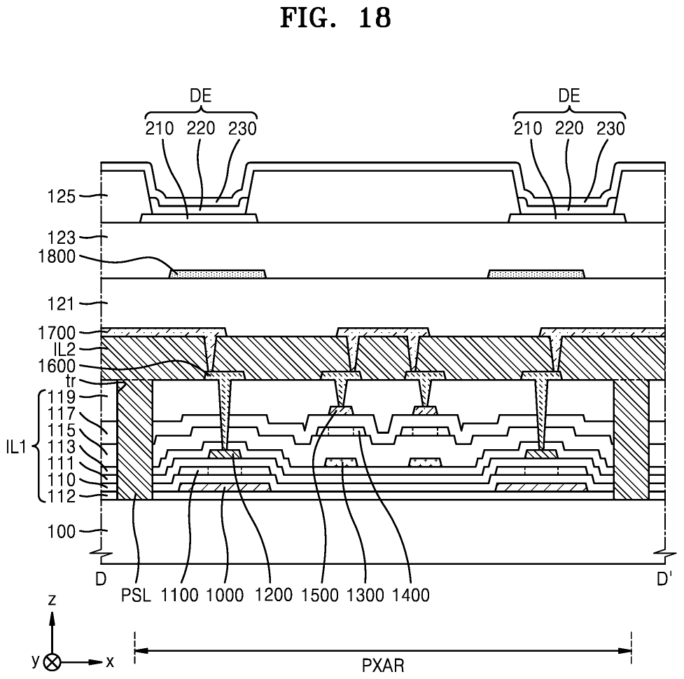

As illustrated in FIGS. 17 and 18 to be described later, a first insulating layer IL1 including an inorganic material may have a trench tr, and a pixel separation layer PSL including an organic material may be disposed in the trench tr. The trench tr of the first insulating layer IL1 may correspond to a boundary between the pixel areas PXAR, and the pixel separation layer PSL may be disposed on the boundary between the pixel areas PXAR.

Components, such as transistors and capacitors, of the display apparatus of FIG. 9 will now be described in greater detail with reference to FIGS. 10 through 16.

A first conductive layer 1000 of FIG. 10 may be disposed on the substrate 100. The first conductive layer 1000 may extend in the first direction (for example, the ±x direction) and the second direction (for example, the ±y direction). The first conductive layer 1000 may overlap a plurality of pixel areas PXAR. The first conductive layer 1000 may include, for example, molybdenum (Mo), aluminum (Al), copper (Cu), or titanium (Ti), and may be formed as a single layer or as a multi-layer. In an embodiment, for example, the first conductive layer 1000 may be a single layer of Mo.

The first conductive layer 1000 may be in a state where a constant voltage is applied thereto. In an embodiment, for example, the driving voltage ELVDD of FIG. 8 may be applied to the first conductive layer 1000.

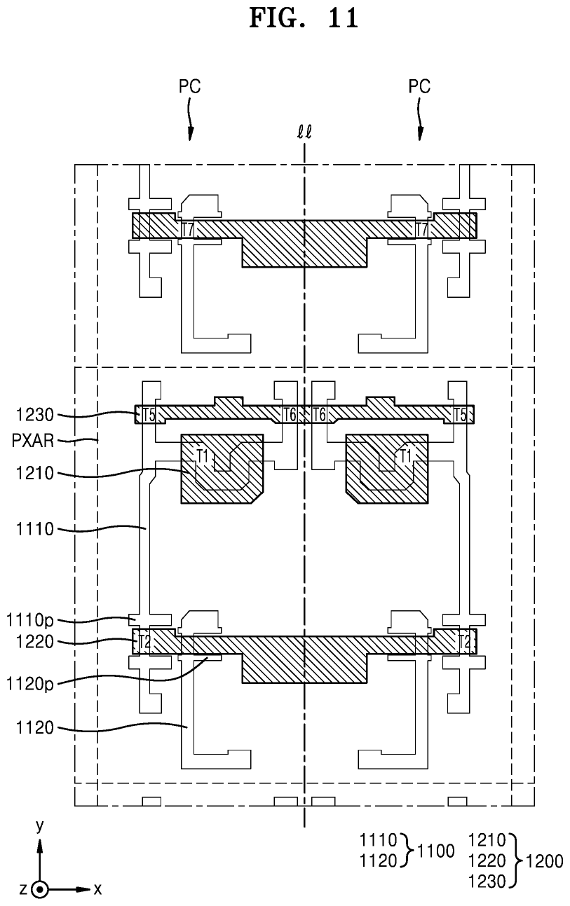

A first semiconductor layer 1100 of FIG. 11 may be disposed on the first conductive layer 1000. The first semiconductor layer 1100 may include a silicon semiconductor material. In an embodiment, for example, the first semiconductor layer 1100 may include amorphous silicon or polysilicon. In an embodiment, the first semiconductor layer 1100 may include polysilicon crystallized at low temperature. In some embodiments, ions may be implanted into at least a portion of the first semiconductor layer 1100.

The first semiconductor layer 1100 may include a first semiconductor pattern 1110 and a second semiconductor pattern 1120. The first semiconductor pattern 1110 and the second semiconductor pattern 1120 may each have an isolated shape within a pixel area PXAR. The first semiconductor pattern 1110 may include a first protrusion 1110p extending in the first direction (e.g., the ±x direction). The second semiconductor pattern 1120 may include a second protrusion 1120p.

A second conductive layer 1200 of FIG. 11 may be disposed on the first semiconductor layer 1100. The second conductive layer 1200 may include, for example, molybdenum (Mo), aluminum (Al), copper (Cu), or titanium (Ti), and may be formed as a single layer or as a multi-layer. In an embodiment, for example, the second conductive layer 1200 may be a single layer of Mo.

The second conductive layer 1200 may include a first gate electrode 1210, a second gate electrode 1220, and a third gate electrode 1230. The first gate electrode 1210, the second gate electrode 1220, and the third gate electrode 1230 may each have an isolated shape within the pixel area PXAR. The second gate electrode 1220 may correspond to the scan line GW of FIG. 8, and the third gate electrode 1230 may correspond to the emission control line EM of FIG. 8. The second gate electrode 1220 disposed in a pixel area PXAR of another row may correspond to the next scan line GB of FIG. 8.

A portion of the first gate electrode 1210 overlapping the first semiconductor pattern 1110 may correspond to the gate of the driving transistor T1. A portion of the second gate electrode 1220 overlapping the second semiconductor pattern 1110 may correspond to the gate of the scan transistor T2. A portion of the third gate electrode 1230 overlapping the first semiconductor pattern 1110 may correspond to the gate of the operation control transistor T5. Another portion of the third gate electrode 1230 overlapping the first semiconductor pattern 1110 may correspond to the gate of the emission control transistor T6. Another portion of the second gate electrode 1220 overlapping the second semiconductor pattern 1120 may correspond to the gate of the anode initializing transistor T7.

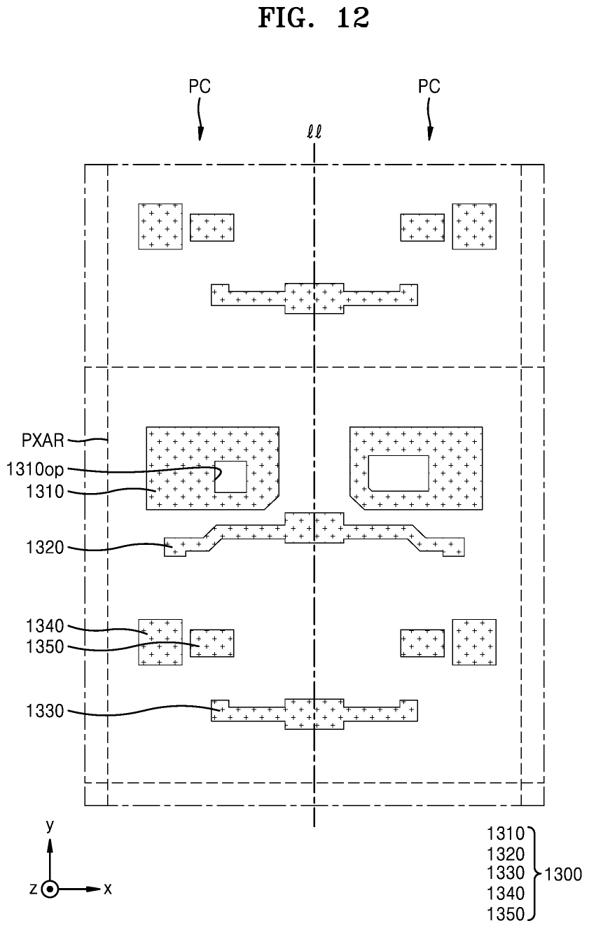

A third conductive layer 1300 of FIG. 12 may be disposed on the second conductive layer 1200. The third conductive layer 1300 may include, for example, molybdenum (Mo), aluminum (Al), copper (Cu), or titanium (Ti), and may be formed as a single layer or as a multi-layer. In an embodiment, for example, the third conductive layer 1300 may be a single layer of Mo.

The third conductive layer 1300 may include a first electrode 1310, a second electrode 1320, a third electrode 1330, a fourth electrode 1340, and a fifth electrode 1350. The first electrode 1310, the second electrode 1320, the third electrode 1330, the fourth electrode 1340, and the fifth electrode 1350 may each have an isolated shape within the pixel area PXAR.

The first electrode 1310 may at least partially overlap the first gate electrode 1210 of FIG. 11. The first electrode 1310 may correspond to the upper electrode CE2 of the storage capacitor Cst of FIG. 8, and the first gate electrode 1210 may correspond to the lower electrode CE1 of the storage capacitor Cst of FIG. 8. The first electrode 1310 and the first gate electrode 1210 may form a capacitance.

An opening 1310op may be defined or formed in the first electrode 1310. The gate of the driving transistor T1 and the drain of the compensating transistor T3 may be connected to each other through the opening 1310op of the first electrode 1310.

The compensating signal Sgc of FIG. 8 may be input to the second electrode 1320, and the initializing signal Sgi of FIG. 8 may be input to the third electrode 1330.

The fourth electrode 1340 may at least partially overlap the first semiconductor pattern 1110 and the second gate electrode 1220. The fourth electrode 1340 may at least partially overlap the first protrusion 1110p of the first semiconductor pattern 1110. The fourth electrode 1340 may be in a floating state.

The fifth electrode 1350 may at least partially overlap the second semiconductor pattern 1120 and the second gate electrode 1220. The fifth electrode 1350 may at least partially overlap the second protrusion 1120p of the second semiconductor pattern 1120. The fifth electrode 1350 may be in a floating state.

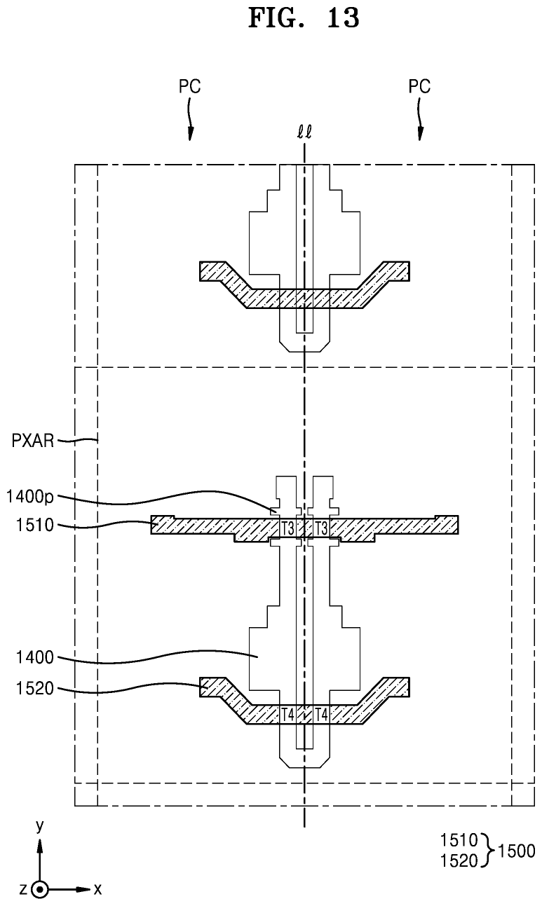

A second semiconductor layer 1400 of FIG. 13 may be disposed on the third conductive layer 1300. The second semiconductor layer 1400 may include a silicon semiconductor material. In an embodiment, for example, the second semiconductor layer 1400 may be formed of Zn oxide, In—Zn oxide, Ga—In—Zn oxide, or the like as a Zn oxide-based material. Alternatively, the second semiconductor layer 1400 may include an In—Ga—Zn—O (IGZO), In—Sn—Zn—O (ITZO), or In—Ga—Sn—Zn—O (IGTZO) semiconductor containing a metal, such as In, Ga, or Sn, in ZnO.

The second semiconductor layer 1400 may have an isolated shape within the pixel area PXAR. The second semiconductor layer 1400 may include a third protrusion 1400p extending in the first direction (e.g., the ±x direction).

A fourth conductive layer 1500 of FIG. 13 may be disposed on the second semiconductor layer 1400. The fourth conductive layer 1500 may include, for example, molybdenum (Mo), aluminum (Al), copper (Cu), or titanium (Ti), and may be formed as a single layer or as a multi-layer. In an embodiment, for example, the fourth conductive layer 1500 may be a single layer of Mo.

The fourth conductive layer 1500 may include a fourth gate electrode 1510 and a fifth gate electrode 1520. The fourth gate electrode 1510 and the fifth gate electrode 1520 may each have an isolated shape within the pixel area PXAR. The fourth gate electrode 1510 may correspond to the compensation gate line GC of FIG. 8, and the fifth gate electrode 1520 may correspond to the initialization gate line GI of FIG. 8.

A portion of the fourth gate electrode 1510 overlapping the second semiconductor layer 1400 may correspond to the gate of the compensating transistor T3. A portion of the fifth gate electrode 1520 overlapping the second semiconductor layer 1400 may correspond to the gate of the gate initializing transistor T4.

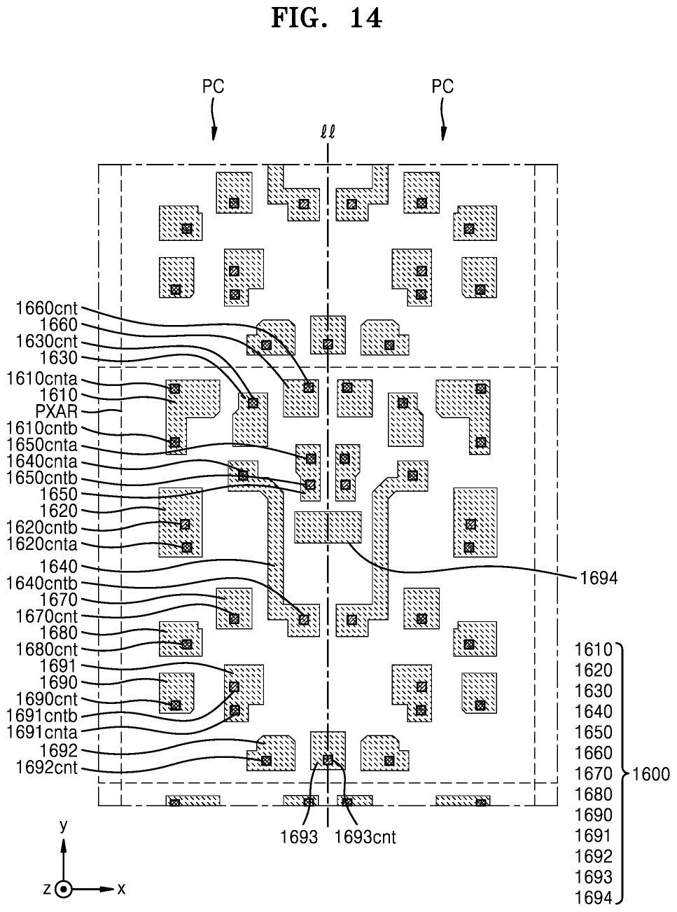

A fifth conductive layer 1600 of FIG. 14 may be disposed on the fourth conductive layer 1500. The fifth conductive layer 1600 may include a conductive material including molybdenum (Mo), aluminum (Al), copper (Cu) or titanium (Ti), and may be a multi-layer or single layer, each layer thereof including at least one selected from the aforementioned materials. In an embodiment, for example, the fifth conductive layer 1600 may have a multi-layer structure of Ti/Al/Ti.

The fifth conductive layer 1600 may include a sixth electrode 1610, a seventh electrode 1620, an eighth electrode 1630, a ninth electrode 1640, a tenth electrode 1650, an eleventh electrode 1660, a twelfth electrode 1670, a thirteenth electrode 1680, a fourteenth electrode 1690, a fifteenth electrode 1691, a sixteenth electrode 1692, a seventeenth electrode 1693, and an eighteenth electrode 1694. Each of the sixth electrode 1610, the seventh electrode 1620, the eighth electrode 1630, the ninth electrode 1640, the tenth electrode 1650, the eleventh electrode 1660, the twelfth electrode 1670, the thirteenth electrode 1680, the fourteenth electrode 1690, the fifteenth electrode 1691, the sixteenth electrode 1692, the seventeenth electrode 1693, and the eighteenth electrode 1694 may have an isolated shape in the pixel area PXAR.

The sixth electrode 1610 may be connected to the first semiconductor pattern 1110 (e.g., the source of the operation control transistor T5) of the first semiconductor layer 1100 through a first first contact hole 1610cnta, and may be connected to the first electrode 1310 through a second first contact hole 1610cntb. The seventh electrode 1620 may be connected to the second electrode 1320 through a first second contact hole 1620cnta and may be connected to the fourth gate electrode 1510 through a second second contact hole 1620cntb. The eighth electrode 1630 may be connected to the third gate electrode 1230 through a third contact hole 1630cnt. The ninth electrode 1640 may be connected to the first gate electrode 1210 through a first fourth contact hole 1640cnta, and may be connected to the second semiconductor layer 1400 (for example, the source of the compensation transistor T3) through a second fourth contact hole 1640cntb. The tenth electrode 1650 may be connected to the first semiconductor pattern 1110 (e.g., the source of the emission control transistor T6) of the first semiconductor layer 1100 through a first fifth contact hole 1650cnta, and may be connected to the second semiconductor layer 1400 (e.g., the drain of the compensating transistor T3) through a second fifth contact hole 1650cntb. The eleventh electrode 1660 may be connected to the first semiconductor pattern 1110 (e.g., the drain of the emission control transistor T6) of the first semiconductor layer 1100 through a sixth contact hole 1660cnt. The twelfth electrode 1670 may be connected to the second semiconductor pattern 1120 (e.g., the drain of the anode initializing transistor T7) of the first semiconductor layer 1100 through a seventh contact hole 1670cnt. The thirteenth electrode 1680 may be connected to the second gate electrode 1220 through an eighth contact hole 1680cnt. The fourteenth electrode 1690 may be connected to the first semiconductor pattern 1110 (e.g., the source of the scan transistor T2) of the first semiconductor layer 1100 through a ninth contact hole 1690cnt. The fifteenth electrode 1691 may be connected to the third electrode 1330 through a first tenth contact hole 1691cnta and may be connected to the fifth gate electrode 1520 through a second tenth contact hole 1691cntb. The sixteenth electrode 1692 may be connected to the second semiconductor pattern 1120 (e.g., the source of the anode initializing transistor T7) of the first semiconductor layer 1100 through an eleventh contact hole 1692cnt. The seventeenth electrode 1693 may be connected to the second semiconductor pattern 1400 (e.g., the source of the gate initializing transistor T4) through a twelfth contact hole 1693cnt.

The eighteenth electrode 1694 may at least partially overlap the second semiconductor pattern 1400 and the fourth gate electrode 1510. The eighteenth electrode 1694 may at least partially overlap the third protrusion 1400p of the second semiconductor layer 1400. The eighteenth electrode 1694 may be in a floating state.

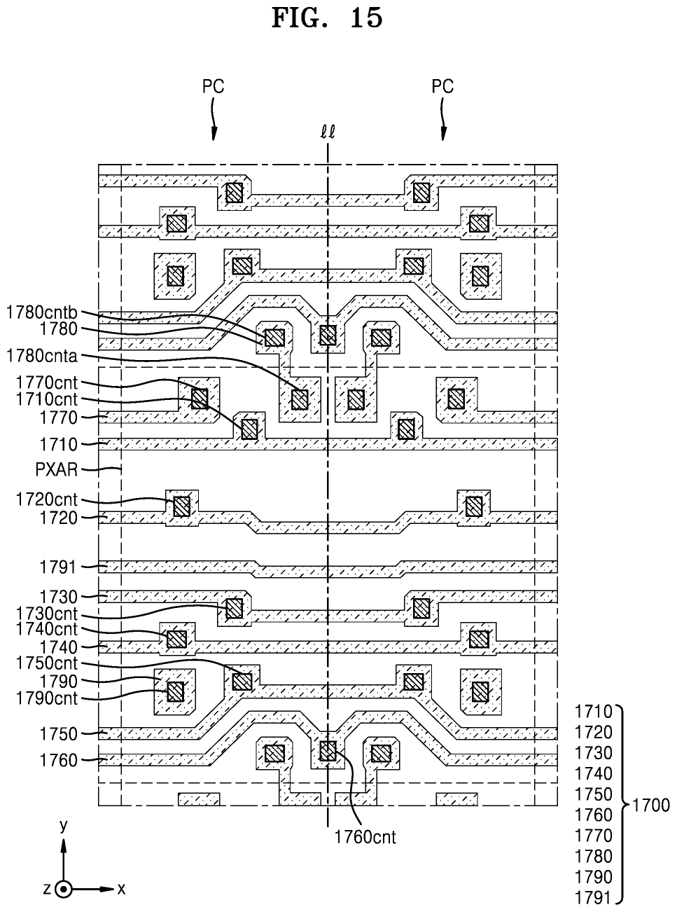

A sixth conductive layer 1700 of FIG. 15 may be disposed on the fifth conductive layer 1600. The sixth conductive layer 1700 may include a conductive material including at least one selected from molybdenum (Mo), aluminum (Al), copper (Cu) and titanium (Ti), and may have a multi-layer or single layer structure, each layer therein including at least one selected from the aforementioned materials. In an embodiment, for example, the sixth conductive layer 1700 may have a multi-layer structure of Ti/Al/Ti.

The sixth conductive layer 1700 may include a first conductive line 1710, a second conductive line 1720, a third conductive line 1730, a fourth conductive line 1740, a fifth conductive line 1750, a sixth conductive line 1750, a nineteenth electrode 1770, a twentieth electrode 1780, a twenty first electrode 1790, and a seventh conductive line 1791. The first conductive line 1710, the second conductive line 1720, the third conductive line 1730, the fourth conductive line 1740, the fifth conductive line 1750, the sixth conductive line 1760, and the seventh conductive line 1791 may each extend substantially in the first direction (e.g., the ±x direction).

The first conductive line 1710 may be connected to the eighth electrode 1630 through a thirteenth contact hole 1710cnt. The emission control signal Sem of FIG. 8 may be applied to the first conductive line 1710. The second conductive line 1720 may be connected to the seventh electrode 1620 through a fourteenth contact hole 1720cnt. The compensation signal Sgc of FIG. 8 may be applied to the second conductive line 1720. The third conductive line 1730 may be connected to the twelfth electrode 1670 through a fifteenth contact hole 1730cnt. A voltage for initializing an anode may be applied to the third conductive line 1730. The fourth conductive line 1740 may be connected to the second gate electrode 1220 through a sixteenth contact hole 1740cnt. The scan signal Sgw of FIG. 8 may be applied to the fourth conductive line 1740. The fifth conductive line 1750 may be connected to the fifteenth electrode 1691 through a seventeenth contact hole 1750cnt. The initialization signal Sgi of FIG. 8 may be applied to the fifth conductive line 1750. The sixth conductive line 1760 may be connected to the seventeenth electrode 1693 through an eighteenth contact hole 1760cnt. A voltage for initializing the gate of the driving transistor T1 may be applied to the sixth conductive line 1760. The nineteenth electrode 1770 may be connected to the sixth electrode 1610 through a nineteenth contact hole 1770cnt. The twentieth electrode 1780 may be connected to the eleventh electrode 1660 through a first twentieth contact hole 1780cnta and may be connected to the sixteenth electrode 1692 through a second twentieth contact hole 1780cntb. The twenty first electrode 1790 may be connected to the fourteenth electrode 1690 through a twenty first contact hole 1790cnt. The common voltage ELVSS of FIG. 8 may be applied to the seventh conductive line 1791.

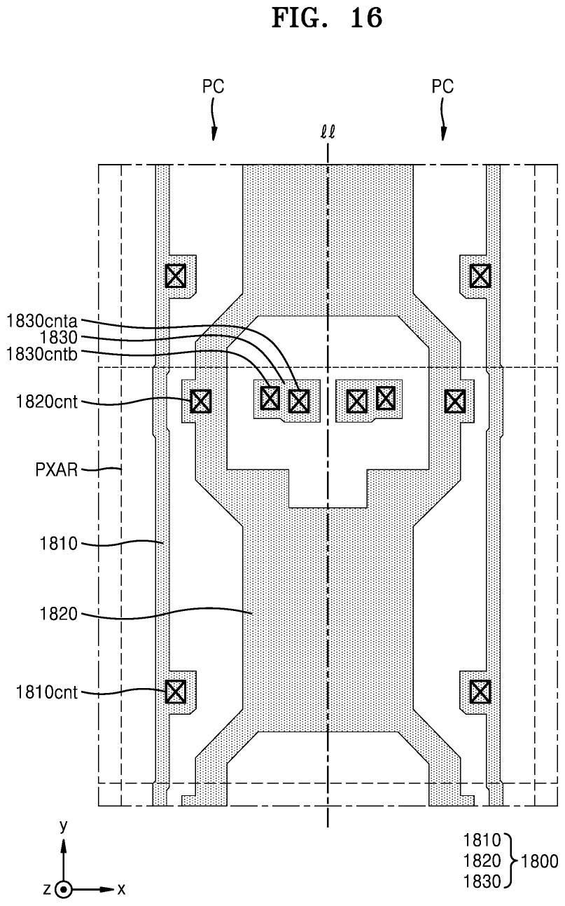

A seventh conductive layer 1800 of FIG. 16 may be disposed on the sixth conductive layer 1700. The seventh conductive layer 1800 may include a conductive material including at least one selected from molybdenum (Mo), aluminum (Al), copper (Cu) and titanium (Ti), and may have a multi-layer or single layer structure, each layer therein including at least one selected from the aforementioned materials. In an embodiment, for example, the seventh conductive layer 1800 may have a multi-layer structure of Ti/Al/Ti.

The seventh conductive layer 1800 may include an eighth conductive line 1810, a ninth conductive line 1820, and a twenty second electrode 1830. The eighth conductive line 1810 and the ninth conductive line 1820 may extend substantially in the second direction (e.g., the ±y direction).

The eighth conductive line 1810 may be connected to the twenty first electrode 1790 through a twenty second contact hole 1810cnt. The eighth conductive line 1810 may correspond to the data line DL of FIG. 8. The ninth conductive line 1820 may be connected to the nineteenth electrode 1770 through a twenty third contact hole 1820cnt. The ninth conductive line 1820 may correspond to the driving voltage line PL of FIG. 8. The twenty second electrode 1830 may be connected to the twentieth electrode 1780 through a first twenty fourth contact hole 1830cnta and may be connected to the anode of the display element through a second twenty fourth contact hole 1830cntb.

FIG. 17 is a schematic plan view illustrating an insulating layer and a pixel separation layer of a display apparatus according to an embodiment in a plurality of pixels.

Referring to FIG. 17, a first insulating layer IL1 including an inorganic material may have a trench tr. The trench tr of the first insulating layer IL1 may correspond to a boundary between the pixel areas PXAR. In a plan view, the trench tr of the first insulating layer IL1 may have a lattice shape (or a mesh structure).

When an external impact is applied to the display apparatus, a crack may occur in an insulating layer including an inorganic material inside the display apparatus. Such a crack generated in one pixel area may grow along the insulating layer including the inorganic material inside the display apparatus, and thus may extend to a pixel area adjacent to the one pixel area. Accordingly, a defect may occur in a plurality of pixels. In an embodiment, the trench tr corresponding to the boundary of the pixel areas PXAR is provided like the first insulating layer IL1 of the display apparatus, such that growth of such a crack may be effectively prevented or minimized.

The pixel separation layer PSL may be disposed in the trench tr of the first insulating layer IL1. The pixel separation layer PSL may correspond to the boundary between the pixel areas PXAR. In a plan view, the pixel separation layer PSL may have a lattice shape (or a mesh structure). As the pixel separation layer PSL is disposed in the trench tr, a step of the first insulating layer IL1 caused by the trench tr may be removed or minimized.

According to an embodiment, the first insulating layer IL1 and the pixel separation layer PSL may include different materials, respectively. In an embodiment, for example, the first insulating layer IL1 may include an inorganic material, and the pixel separation layer PSL may include an organic material. Because the pixel separation layer PSL includes an organic material, growing of a crack formed in the first insulating layer IL1 including an inorganic material in one pixel due to an external impact into a pixel adjacent to the one pixel may be effectively prevented or minimized.

FIG. 18 is a cross-sectional view of a portion of FIG. 17 taken along line D-D′.

Referring to FIG. 18, the first insulating layer IL1 may have the trench tr corresponding to the boundary between pixel areas PXAR. The first insulating layer IL1 may include a barrier layer 112, a buffer layer 110, a first gate insulating layer 111, a second gate insulating layer 113, a first interlayer insulating layer 115, a third gate insulating layer 117, and a second interlayer insulating layer 119. The pixel separation layer PSL may be disposed in the trench tr of the first insulating layer IL1.

In an embodiment shown in FIG. 18, the trench tr may be formed by removing at least respective portions of the barrier layer 112, the buffer layer 110, the first gate insulating layer 111, the second gate insulating layer 113, the first interlayer insulating layer 115, the third gate insulating layer 117, and the second interlayer insulating layer 119. According to an alternative embodiment, the trench tr may be formed by removing at least respective portions of the buffer layer 110, the first gate insulating layer 111, the second gate insulating layer 113, the first interlayer insulating layer 115, the third gate insulating layer 117, and the second interlayer insulating layer 119.

Components included in the display apparatus 1 will now be described in greater detail according to a stacked structure with reference to FIG. 18.

The substrate 100 may include glass or polymer resin. Examples of the polymer resin may include polyethersulphone, polyacrylate, polyetherimide, polyethylene naphthalate, polyethylene terephthalate, polyphenylene sulfide, polyarylate, polyimide, polycarbonate, and cellulose acetate propionate. The substrate 100 including polymer resin may have flexible, rollable, or bendable characteristics. The substrate 100 may have a multi-layered structure including a layer including the aforementioned polymer resin and an inorganic layer (not shown).

The barrier layer 112 may be arranged on the substrate 100. The barrier layer 112 may prevent or minimize infiltration of impurities from the substrate 100 and the like into the first semiconductor layer 1100 and the second semiconductor layer 1400. The barrier layer 112 may include an inorganic material (such as oxide or nitride), an organic material, or an organic and inorganic compound, and may be a single layer or multiple layers of an inorganic material and an organic material.

The first insulating layer IL1 may be disposed on the barrier layer 112. The first insulating layer IL1 may have the trench tr corresponding to the boundary between pixel areas PXAR. The first insulating layer IL1 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO₂), or the like.

The pixel separation layer PSL may be disposed in the trench tr of the first insulating layer IL1. The pixel separation layer PSL may be a single layer including an organic material or a multi-layer formed by stacking single layers each including an organic material. In an embodiment, for example, the pixel separation layer PSL may include a polymer known in the art or commercially available such as benzocyclobutene (BCB), polyimide, hexamethyldisiloxane (HMDSO), polymethyl methacrylate (PMMA) or polystyrene (PS), a polymer derivative having a phenol-based group, an acryl-based polymer, an imide-based polymer, an acryl ether-based polymer, an amide-based polymer, a fluorine-based polymer, a p-xylene-based polymer, a vinyl alcohol-based polymer, a blend thereof, or the like.

The first insulating layer 1000 may be disposed on the barrier layer 112. The buffer layer 110 covering the first conductive layer 1000 may be disposed on the barrier layer 112. The first semiconductor layer 1100 may be disposed on the buffer layer 110. The first semiconductor layer 1100 may include a channel region, and a source region and a drain region respectively arranged on opposing sides of the channel region. The first semiconductor layer 1100 may have a single-layer or multi-layer structure. The first semiconductor layer 1100 may at least partially overlap the conductive layer 1000.

The first gate insulating layer 111 may be disposed on the buffer layer 110 to cover the first semiconductor layer 1100. The second conductive layer 1200 may be disposed on the first gate insulating layer 111. The second conductive layer 1200 may at least partially overlap the first semiconductor layer 1100.

The second gate insulating layer 113 may be disposed on the first gate insulating layer 111 to cover the second conductive layer 1200. The third conductive layer 1300 may be disposed on the second gate insulating layer 113. The first interlayer insulating layer 115 may be disposed on the second gate insulating layer 113 to cover the third conductive layer 1300. The second semiconductor layer 1400 may be disposed on the first interlayer insulating layer 115. The third gate insulating layer 117 may be disposed on the first interlayer insulating layer 115 to cover the second semiconductor layer 1400. The fourth conductive layer 1500 may be disposed on the third gate insulating layer 117. The fourth conductive layer 1500 may at least partially overlap the second semiconductor layer 1400.

The second interlayer insulating layer 119 may be disposed on the third gate insulating layer 117 to cover the fourth conductive layer 1500. The fifth conductive layer 1600 may be disposed on the second interlayer insulating layer 119. The fifth conductive layer 1600 may be connected to the second conductive layer 1200 through contact holes defined or formed in the second gate insulating layer 113, the first interlayer insulating layer 115, the third gate insulating layer 117, and the second interlayer insulating layer 119. The fifth conductive layer 1600 may be connected to the fourth conductive layer 1500 through the contact hole defined or formed in the second interlayer insulating layer 119.

Although not shown in FIG. 18, the fifth conductive layer 1600 may be connected to the second conductive layer 1100 through the contact holes defined or formed in the first gate insulating layer 111, the second gate insulating layer 113, the first interlayer insulating layer 115, the third gate insulating layer 117, and the second interlayer insulating layer 119. The fifth conductive layer 1600 may be connected to the second conductive layer 1300 through the contact holes defined or formed in the first interlayer insulating layer 115, the third gate insulating layer 117, and the second interlayer insulating layer 119. The fifth conductive layer 1600 may be connected to the second semiconductor layer 1400 through the contact holes defined or formed in the third gate insulating layer 117 and the second interlayer insulating layer 119.

The second insulating layer IL2 may be disposed on the second interlayer insulating layer 119 to cover the fifth conductive layer 1600. The second insulating layer IL2 may be a single layer including an organic material or a multi-layer formed by stacking single layers each including an organic material, and provides a flat upper surface. The second insulating layer IL2 may include a polymer known in the art or commercially available such as benzocyclobutene (BCB), polyimide, hexamethyldisiloxane (HMDSO), polymethyl methacrylate (PMMA) or polystyrene (PS), a polymer derivative having a phenol-based group, an acryl-based polymer, an imide-based polymer, an acryl ether-based polymer, an amide-based polymer, a fluorine-based polymer, a p-xylene-based polymer, a vinyl alcohol-based polymer, a blend thereof, or the like.

According to an embodiment, the pixel separation layer PSL and the second insulating layer IL2 may be integrally formed with each other as a single unitary and indivisible part.

The sixth conductive layer 1700 may be arranged on the second insulating layer IL2. The sixth conductive layer 1700 may be connected to the fifth conductive layer 1600 through the contact hole defined or formed in the second insulating layer IL2.

A first planarization layer 121 may be disposed on the second insulating layer IL2 to cover the sixth conductive layer 1700. The first planarization layer 121 may have a single-layer or multi-layer structure of a layer including an organic material, and provides a flat upper surface. The first planarization layer 121 may include a polymer known in the art or commercially available such as benzocyclobutene (BCB), polyimide, hexamethyldisiloxane (HMDSO), polymethyl methacrylate (PMMA) or polystyrene (PS), a polymer derivative having a phenol-based group, an acryl-based polymer, an imide-based polymer, an acryl ether-based polymer, an amide-based polymer, a fluorine-based polymer, a p-xylene-based polymer, a vinyl alcohol-based polymer, a blend thereof, or the like.

The seventh conductive layer 1800 may be disposed on the first planarization layer 121. Although not shown in FIG. 18, the seventh conductive layer 1800 may be connected to the sixth conductive layer 1700 through a contact hole defined or formed in the first planarization layer 121.

A second planarization layer 123 may be disposed on the first planarization layer 121 to cover the seventh conductive layer 1800. The second planarization layer 123 may have a single-layer or multi-layer structure of a layer including an organic material, and provides a flat upper surface. The second planarization layer 123 may include a polymer known in the art or commercially available such as benzocyclobutene (BCB), polyimide, hexamethyldisiloxane (HMDSO), polymethyl methacrylate (PMMA) or polystyrene (PS), a polymer derivative having a phenol-based group, an acryl-based polymer, an imide-based polymer, an acryl ether-based polymer, an amide-based polymer, a fluorine-based polymer, a p-xylene-based polymer, a vinyl alcohol-based polymer, a blend thereof, or the like.

A display element DE may be arranged on the second planarization layer 123. The display element DE may be an organic light-emitting diode OLED, and may include a pixel electrode 210, an intermediate layer 220 including an organic emission layer, and an opposite electrode 230.

The pixel electrode 210 may be a (semi) light-transmissive electrode or a reflective electrode. According to some embodiments, the pixel electrode 210 may include a reflective layer formed of silver (Ag), magnesium (Mg), aluminum (Al), platinum (Pt), palladium (Pd), gold (Au), nickel (Ni), neodymium (Nd), iridium (Ir), chromium (Cr), or a compound thereof, and a transparent or semi-transparent electrode layer formed on the reflective layer. The transparent or semi-transparent electrode layer may include at least one selected from indium tin oxide (ITO), indium zinc oxide (IZO), zinc oxide (ZnO), indium oxide (In₂O₃), indium gallium oxide (IGO), and aluminum zinc oxide (AZO). According to some embodiments, the pixel electrode 210 may be formed as ITO/Ag/ITO.

A pixel defining layer 125 may be arranged on the second planarization layer 123 in a display area of the substrate 100. The pixel defining layer 125 may cover an edge of the pixel electrode 210 and may be provided with an opening that exposes a center portion of the pixel electrode 210. The opening may define an emission region of the display element DE.

The pixel defining layer 125 may prevent an electric arc or the like from occurring on the edge of the pixel electrode 210 by increasing a distance between the edge of the pixel electrode 210 and the opposite electrode 230 that is over the pixel electrode 210.

The pixel defining layer 125 may include or be formed of at least one organic insulating material selected from polyimide, polyamide, acryl resin, benzocyclobutene, and a phenolic resin, by using a method such as spin coating. The pixel defining layer 125 may include an organic insulating material. Alternatively, the pixel defining layer 125 may include an inorganic insulating material such as silicon nitride, silicon oxynitride, or silicon oxide. Alternatively, the pixel defining layer 125 may include an organic insulating material and an inorganic insulating material. According to some embodiments, the pixel defining layer 125 may include a light shielding material, and may have a black color. The light shielding material may include carbon black, carbon nanotubes, resin or paste including a black pigment, metal particles (e.g., nickel, aluminum, molybdenum, and an alloy thereof), metal oxide particles (e.g., a chromium oxide), or metal nitride particles (e.g., a chromium nitride). In an embodiment where the pixel defining layer 125 includes the light shielding material, external light reflection due to metal structures arranged under the pixel defining layer 125 may be reduced.

The intermediate layer 220 may be located in the opening defined in the pixel defining layer 125 and may include an organic emission layer. The organic emission layer may include an organic material including a fluorescent or phosphorescent material that emits red, green, blue, or white light. The organic emission layer may include a low molecular organic material or a high molecular organic material, and a functional layer, such as a hole transport layer (HTL), a hole injection layer (HIL), an electron transport layer (ETL), or an electron injection layer (EIL), may be selectively further arranged below and above the organic emission layer.

The opposite electrode 230 may be a light-transmissive electrode or a reflective electrode. According to some embodiments, the opposite electrode 230 may be a transparent or semi-transparent electrode, and may include a thin metal film having a small work function, including lithium (Li), calcium (Ca), lithium fluoride/calcium (LiF/Ca), lithium fluoride/aluminum (LiF/Al), aluminum (Al), silver (Ag), magnesium (Mg), or a compound thereof. A transparent conductive oxide (TCO) layer including, for example, ITO, IZO, ZnO, or In₂O₃, may be further arranged on the thin metal film. The opposite electrode 230 may extend over the display area, and may be arranged on the intermediate layer 220 and the pixel defining layer 125. The opposite electrode 230 may be formed as a single body constituting a plurality of display elements DE, and thus may correspond to a plurality of pixel electrodes 210.

Because the display elements DE may be easily damaged by external moisture, oxygen, or the like, an encapsulation layer (not shown) may cover and protect the display elements DE. The encapsulation layer may cover the display area, and may extend to at least a portion of a peripheral area. The encapsulation layer may include a first inorganic encapsulation layer, an organic encapsulation layer, and a second inorganic encapsulation layer.

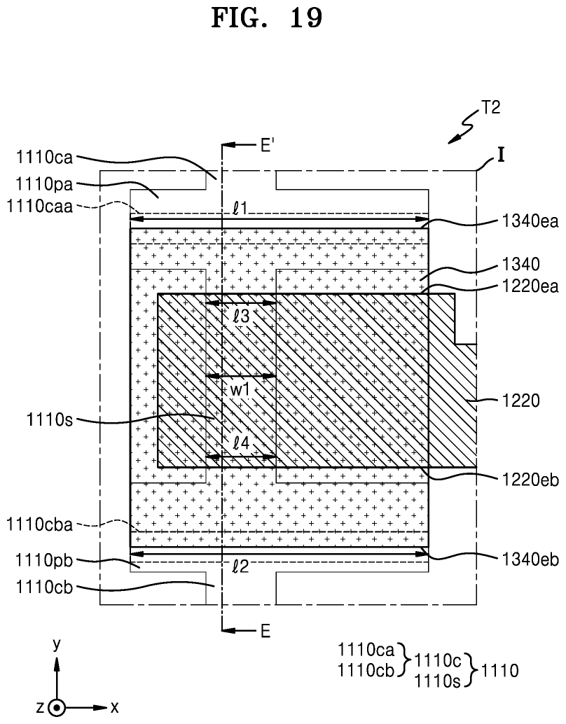

FIG. 19 is an enlarged plan view schematically illustrating a portion I of FIG. 9. In detail, FIG. 19 shows the first semiconductor pattern 1110 of the first semiconductor layer 1100, the second gate electrode 1220 of the second conductive layer 1200, and the fourth electrode 1340 of the third conductive layer 1300. In FIG. 19, a portion where the scan transistor T2 of FIG. 9 is disposed is focused on and described. However, this description may be equally applied to a portion where the anode initializing transistor T7 of FIG. 9 is disposed.

Referring to FIG. 19, the first semiconductor pattern 1110 of the first semiconductor layer 1100 may include a conductive region 1110c and a first semiconductor region 1110s. The conductive region 1110c and the first semiconductor region 1110s may be adjacent to each other. In an embodiment, for example, as shown in FIG. 19, the conductive region 1110c may include a first conductive region 1110ca and a second conductive region 1110cb. The first semiconductor region 1110s may be located between the first conductive region 1110ca and the second conductive region 1110cb.

According to an embodiment, the conductive region 1110c may include a protrusion. In an embodiment, for example, the first conductive region 1110ca may include a first protrusion 1110pa extending in the first direction (e.g., the ±x direction). The second conductive region 1110cb may include a second protrusion 1110pb extending in the first direction (e.g., the ±x direction).

The second gate electrode 1220 of the second conductive layer 1200 may at least partially overlap the first semiconductor pattern 1110. In an embodiment, for example, the second gate electrode 1220 may at least partially overlap the first semiconductor region 1110s of the first semiconductor pattern 1110.

The fourth electrode 1340 of the third conductive layer 1300 may at least partially overlap the second gate electrode 1220 and the first semiconductor pattern 1110. The fourth electrode 1340 may be in a floating state.

According to an embodiment, the fourth electrode 1340 may have an edge (or a side) extending in the first direction (e.g., the ±x direction) and at least partially overlapping the conductive region 1110c. In an embodiment, for example, the fourth electrode 1340 may have a first edge 1340ea extending in the first direction (e.g., the ±x direction) and at least partially overlapping the first conductive region 1110ca, and a second edge 1340eb extending in the first direction (e.g., the ±x direction) and at least partially overlapping the second conductive region 1110cb. The second edge 1340eb of the fourth electrode 1340 may be opposite to the first edge 1340ea of the fourth electrode 1340. The first edge 1340ea of the fourth electrode 1340 may at least partially overlap the first protrusion 1110pa of the first conductive region 1110ca. The second edge 1340eb of the fourth electrode 1340 may at least partially overlap the second protrusion 1110pb of the second conductive region 1110cb.

According to an embodiment, a first length l1 of a first portion 1110caa of the first conductive region 1110ca in the first direction (e.g., the ±x direction) may be greater than a first width w1 of the first semiconductor region 1110s in the first direction (e.g., the ±x direction). The first portion 1110caa of the first conductive region 1110ca is a portion that overlaps the first edge 1340ea of the fourth electrode 1340 in the first conductive region 1110ca. The first portion 1110caa of the first conductive region 1110ca is a portion corresponding to the first edge 1340ea of the fourth electrode 1340.

According to an embodiment, a second length l2 of a second portion 1110cba of the second conductive region 1110cb in the first direction (e.g., the ±x direction) may be greater than the first width w1 of the first semiconductor region 1110s in the first direction (e.g., the ±x direction). The second portion 1110cba of the second conductive region 1110cb is a portion that overlaps the second edge 1340eb of the fourth electrode 1340 in the second conductive region 1110cb. The second portion 1110cba of the second conductive region 1110cb is a portion corresponding to the second edge 1340eb of the fourth electrode 1340.

According to an embodiment, the first length l1 of the first portion 1110caa of the first conductive region 1110ca may be greater than a third length l3 of a portion of the first semiconductor pattern 1110 corresponding to a third edge 1220ea of the second gate electrode 1220 in the first direction (e.g., the ±x direction). In such an embodiment, the first length l1 of the first portion 1110caa of the first conductive region 1110ca may be greater than the length l3 of a boundary between the first conductive region 1110ca and the first semiconductor region 1110s. In a plan view, the third edge 1220ea of the second gate electrode 1220 corresponds to the boundary between the first conductive region 1110ca and the first semiconductor region 1110s.

According to an embodiment, the second length l2 of the second portion 1110cba of the second conductive region 1110cb may be greater than a fourth length l4 of another portion of the first semiconductor pattern 1110 corresponding to a fourth edge 1220eb of the second gate electrode 1220 in the first direction (e.g., the ±x direction). In such an embodiment, the second length l2 of the second portion 1110cba of the second conductive region 1110cb may be greater than the length l4 of a boundary between the second conductive region 1110cb and the first semiconductor region 1110s. In a plan view, the fourth edge 1220eb of the second gate electrode 1220 corresponds to the boundary between the second conductive region 1110cb and the first semiconductor region 1110s.

When the display apparatus receives an impact from the outside, a crack may occur in a portion of the first semiconductor pattern 1110 corresponding to the third and fourth edges 1220ea and 1220eb of the second gate electrode 1220. In an embodiment, the fourth electrode 1340 is disposed to at least partially overlap the second gate electrode 1220, such that the portion of the first semiconductor pattern 1110 corresponding to the third and fourth edges 1220ea and 1220eb of the second gate electrode 1220 may be protected by the fourth electrode 1340. Thus, even when the display apparatus receives an impact from the outside, a crack may be effectively prevented from occurring in the portion of the first semiconductor pattern 1110 corresponding to the third and fourth edges 1220ea and 1220eb of the second gate electrode 1220. In an embodiment, a crack may occur at a portion of the first semiconductor pattern 1110 corresponding to the first edge 1340ea and the second edge 1340eb of the fourth electrode 1340 due to an external impact. In such an embodiment, the first semiconductor pattern 1110 includes a protrusion as shown in FIG. 19, such that the area of the first semiconductor pattern 1110 corresponding to the first edge 1340ea and the second edge 1340eb of the fourth electrode 1340 may increase, and thus such cracking may be effectively prevented.

When a crack occurs in a semiconductor layer of the scan transistor T2, a path for applying the data voltage to the driving transistor T1 is disconnected. When the data voltage is not properly applied to the driving transistor T1, a bright spot occurs in the display apparatus. According to an embodiment, because the semiconductor layer of the scan transistor T2 has a protrusion to prevent cracking, occurrence of a bright spot in the display apparatus may be effectively prevented.

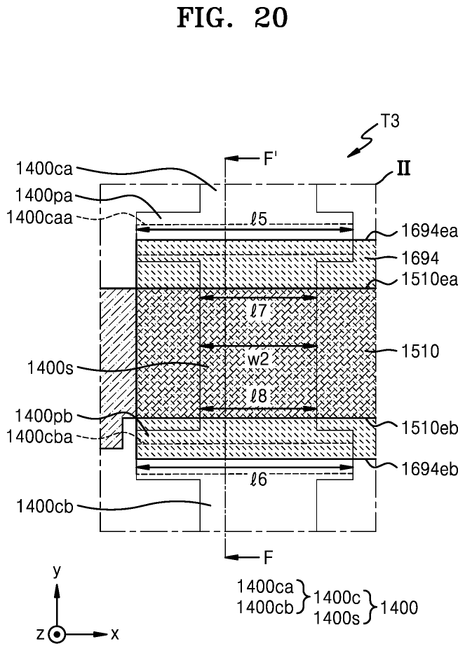

FIG. 20 is an enlarged plan view schematically illustrating a portion II of FIG. 9. In detail, FIG. 20 shows the second semiconductor layer 1400, the fourth gate electrode 1510 of the fourth conductive layer 1500, and the eighteenth electrode 1694 of the fifth conductive layer 1600 in the portion II of FIG. 9 (e.g., a portion where the compensating transistor T3 is disposed).

Referring to FIG. 20, the second semiconductor layer 1400 may include a conductive region 1400c and a second semiconductor region 1400s. The conductive region 1400c and the second semiconductor region 1400s may be adjacent to each other. In an embodiment, for example, as shown in FIG. 20, the conductive region 1400c may include a third conductive region 1400ca and a fourth conductive region 1400cb. The second semiconductor region 1400s may be located between the third conductive region 1400ca and the fourth conductive region 1400cb.

According to an embodiment, the conductive region 1400c may include a protrusion. In an embodiment, for example, the third conductive region 1400ca may include a third protrusion 1400pa extending in the first direction (e.g., the ±x direction). The fourth conductive region 1400cb may include a fourth protrusion 1400pb extending in the first direction (e.g., the ±x direction).

The fourth gate electrode 1510 of the fourth conductive layer 1500 may at least partially overlap the second semiconductor layer 1400. In an embodiment, for example, the fourth gate electrode 1510 may at least partially overlap the second semiconductor region 1400s of the second semiconductor layer 1400.

The eighteenth electrode 1694 of the fifth conductive layer 1600 may at least partially overlap the fourth gate electrode 1510 and the second semiconductor layer 1400. The eighteenth electrode 1694 may be in a floating state.

According to an embodiment, the eighteenth electrode 1694 may have an edge extending in the first direction (e.g., the ±x direction) and at least partially overlapping the conductive region 1400c. In an embodiment, for example, the eighteenth electrode 1694 may have a fifth edge 1694ea extending in the first direction (e.g., the ±x direction) and at least partially overlapping the third conductive region 1400ca, and a sixth edge 1694eb extending in the first direction (e.g., the ±x direction) and at least partially overlapping the fourth conductive region 1400cb. The sixth edge 1694eb of the eighteenth electrode 1694 may be opposite to the fifth edge 1694ea of the eighteenth electrode 1694. The fifth edge 1694ea of the eighteenth electrode 1694 may at least partially overlap the third protrusion 1400pa of the third conductive region 1400ca. The sixth edge 1694eb of the eighteenth electrode 1694 may at least partially overlap the fourth protrusion 1400pb of the fourth conductive region 1400cb.

According to an embodiment, a fifth length l5 of a third portion 1400caa of the third conductive region 1400ca in the first direction (e.g., the ±x direction) may be greater than a second width w2 of the second semiconductor region 1400s in the first direction (e.g., the ±x direction). The third portion 1400caa of the third conductive region 1400ca is a portion that overlaps the fifth edge 1694ea of the eighteenth electrode 1694 in the third conductive region 1400ca. The third portion 1400caa of the third conductive region 1400ca is a portion corresponding to the fifth edge 1694ea of the eighteenth electrode 1694.

According to an embodiment, a sixth length l6 of a fourth portion 1400cba of the fourth conductive region 1400cb in the first direction (e.g., the ±x direction) may be greater than the second width w2 of the second semiconductor region 1400s in the first direction (e.g., the ±x direction). The fourth portion 1400cba of the fourth conductive region 1400cb is a portion that overlaps the sixth edge 1694eb of the eighteenth electrode 1694 in the fourth conductive region 1400cb. The fourth portion 1400cba of the fourth conductive region 1400cb is a portion corresponding to the sixth edge 1694eb of the eighteenth electrode 1694.

According to an embodiment, the fifth length l5 of the third portion 1400caa of the third conductive region 1400ca may be greater than a seventh length U of a portion of the second semiconductor layer 1400 corresponding to the seventh edge 1510ea of the fourth gate electrode 1510 in the first direction (e.g., the ±x direction). In such an embodiment, the fifth length l5 of the third portion 1400caa of the third conductive region 1400ca may be greater than the length U of a boundary between the third conductive region 1400ca and the second semiconductor region 1400s. In a plan view, the seventh edge 1510ea of the fourth gate electrode 1510 corresponds to the boundary between the third conductive region 1400ca and the second semiconductor region 1400s.

According to an embodiment, the sixth length l6 of the fourth portion 1400cba of the fourth conductive region 1400cb may be greater than an eighth length l8 of another portion of the second semiconductor layer 1400 corresponding to the eighth edge 1510eb of the fourth gate electrode 1510 in the first direction (e.g., the ±x direction). In such an embodiment, the sixth length l6 of the fourth portion 1400cba of the fourth conductive region 1400cb may be greater than the length l8 of a boundary between the fourth conductive region 1400cb and the second semiconductor region 1400s. In a plan view, the eighth edge 1510eb of the fourth gate electrode 1510 corresponds to the boundary between the fourth conductive region 1400cb and the second semiconductor region 1400s.

When the display apparatus receives an impact from the outside, a crack may occur in a portion of the second semiconductor layer 1400 corresponding to the seventh and eighth edges 1510ea and 1510eb of the fourth gate electrode 1510. In an embodiment, the eighteenth electrode 1694 is disposed to at least partially overlap the fourth gate electrode 1510, such that the portion of the second semiconductor layer 1400 corresponding to the seventh and eighth edges 1510ea and 1510eb of the fourth gate electrode 1510 may be protected by the eighteenth electrode 1694. Thus, even when the display apparatus receives an impact from the outside, a crack may be effectively prevented from occurring in the portion of the second semiconductor layer 1400 corresponding to the seventh and eighth edges 1510ea and 1510eb of the fourth gate electrode 1510. In an embodiment, a crack may occur at a portion of the second semiconductor layer 1400 corresponding to the fifth edge 1694ea and the sixth edge 1694eb of the eighteenth electrode 1694 due to an external impact. In such an embodiment, the second semiconductor layer 1400 has a protrusion as shown in FIG. 20, such that the area of the second semiconductor layer 1400 corresponding to the fifth edge 1694ea and the sixth edge 1694eb of the eighteenth electrode 1694 may increase, and thus such cracking may be prevented.

When a crack occurs in a semiconductor layer of the compensating transistor T3, a path for applying the data voltage to the driving transistor T1 is disconnected. When the data voltage is not properly applied to the driving transistor T1, a bright spot occurs in the display apparatus. According to an embodiment, because the semiconductor layer of the compensating transistor T3 has a protrusion to prevent cracking, occurrence of a bright spot in the display apparatus may be prevented.

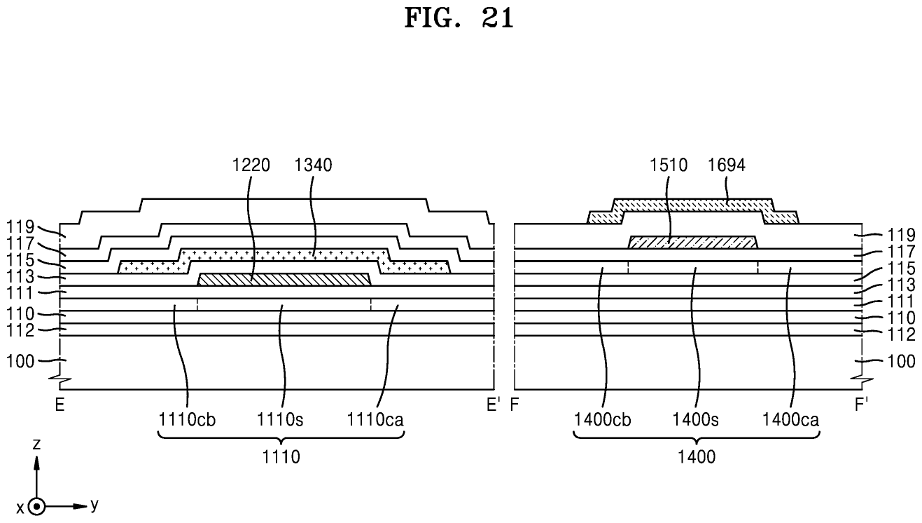

FIG. 21 is a cross-sectional view of a portion of FIG. 19 and a portion of FIG. 20 taken along lines E-E′ and F-F′, respectively.

Referring to FIG. 21, the first semiconductor pattern 1110 may be interposed between the buffer layer 110 and the first gate insulating layer 111. The first semiconductor pattern 1110 may include the first conductive region 1110ca, the second conductive region 1110cb, and the first semiconductor region 1110s between the first conductive region 1110ca and the second conductive region 1110cb.

The second gate electrode 1220 may be interposed between the first gate insulating layer 111 and the second gate insulating layer 113. The fourth electrode 1340 may be interposed between the second gate insulating layer 113 and the first interlayer insulating layer 115.

The second semiconductor layer 1400 may be interposed between the first interlayer insulating layer 115 and the third gate insulating layer 117. The second semiconductor layer 1400 may include the third conductive region 1400ca, the fourth conductive region 1400cb, and the second semiconductor region 1400s between the third conductive region 1400ca and the fourth conductive region 1400cb.

The fourth gate electrode 1510 may be interposed between the third gate insulating layer 117 and the second interlayer insulating layer 119. The eighteenth electrode 1694 may be disposed on the second interlayer insulating layer 119.

In FIG. 21, the fourth electrode 1340 is interposed between the second gate insulating layer 113 and the first interlayer insulating layer 115. According to another embodiment, the fourth electrode 1340 may be interposed between the third gate insulating layer 117 and the second interlayer insulating layer 119. According to another embodiment, the fourth electrode 1340 may be disposed on the second interlayer insulating layer 119.

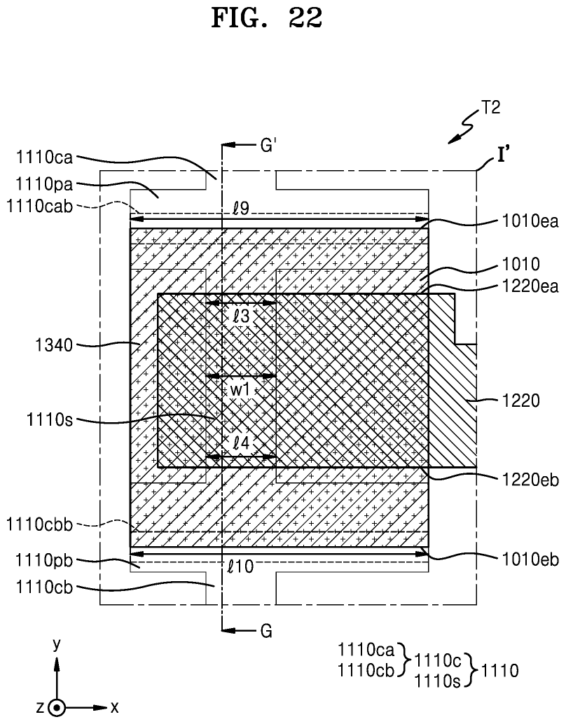

FIG. 22 is an enlarged plan view schematically illustrating a portion of FIG. 9. FIG. 22 is a modification of FIG. 19, and is thus different therefrom in the structure of an electrode. Hereinafter, overlapping contents therebetween will be replaced with the description of FIG. 19, and the differences will be mainly described.

Referring to FIG. 22, the display apparatus may further include a twenty third electrode 1010. The twenty third electrode 1010 may at least partially overlap the second gate electrode 1220, the first semiconductor pattern 1110, and the fourth electrode 1340.

The twenty third electrode 1010 may include at least one metal selected from aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and copper (Cu) and may have a single-layered or multi-layered structure.

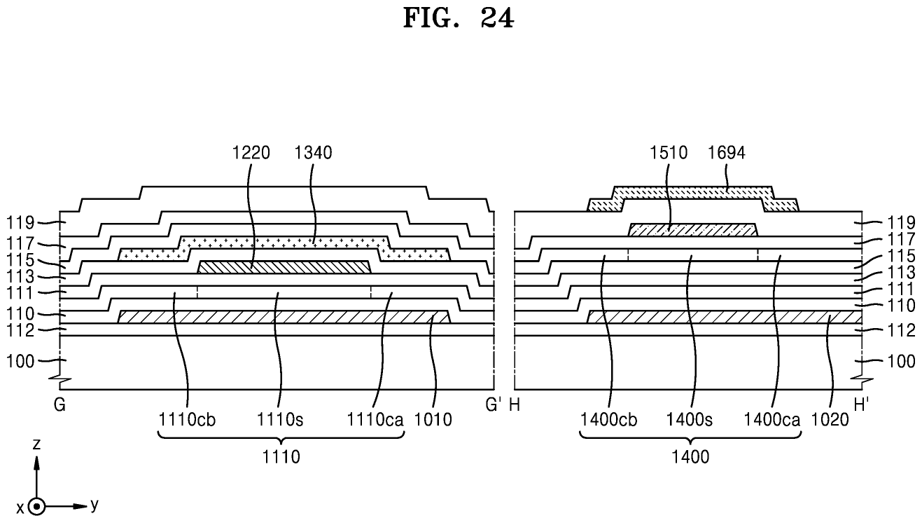

According to an embodiment, as shown in FIG. 24, the twenty third electrode 1010 may be interposed between the substrate 100 and the first semiconductor pattern 1110. The twenty third electrode 1010 may be interposed between the barrier layer 112 and the buffer layer 110.

According to an embodiment, the twenty third electrode 1010 may be in a floating state.

According to an embodiment, the twenty third electrode 1010 may have an edge extending in the first direction (e.g., the ±x direction) and at least partially overlapping the conductive region 1110c. In an embodiment, for example, the twenty third electrode 1010 may have a ninth edge 1010ea extending in the first direction (e.g., the ±x direction) and at least partially overlapping the first conductive region 1110ca, and a tenth edge 1010eb extending in the first direction (e.g., the ±x direction) and at least partially overlapping the second conductive region 1110cb. The tenth edge 1010eb of the twenty third electrode 1010 may be opposite to the ninth edge 1010ea of the twenty third electrode 1010. The ninth edge 1010ea of the twenty third electrode 1010 may at least partially overlap the first protrusion 1110pa of the first conductive region 1110ca. The tenth edge 1010eb of the twenty third electrode 1010 may at least partially overlap the second protrusion 1110pb of the second conductive region 1110cb.

According to an embodiment, a ninth length l9 of a fifth portion 1110cab of the first conductive region 1110ca in the first direction (e.g., the ±x direction) may be greater than the first width w1 of the first semiconductor region 1110s in the first direction (e.g., the ±x direction). The fifth portion 1110cab of the first conductive region 1110ca is a portion that overlaps the ninth edge 1010ea of the twenty third electrode 1010 in the first conductive region 1110ca. The fifth portion 1110cab of the first conductive region 1110ca is a portion corresponding to the ninth edge 1010ea of the twenty third electrode 1010.

According to an embodiment, a tenth length l10 of a sixth portion 1110cbb of the second conductive region 1110cb in the first direction (e.g., the ±x direction) may be greater than the first width w1 of the first semiconductor region 1110s in the first direction (e.g., the ±x direction). The sixth portion 1110cbb of the second conductive region 1110cb is a portion that overlaps the tenth edge 1010eb of the twenty third electrode 1010 in the second conductive region 1110cb. The sixth portion 1110cbb of the second conductive region 1110cb is a portion corresponding to the tenth edge 1010eb of the twenty third electrode 1010.

According to an embodiment, the ninth length l9 of the fifth portion 1110cab of the first conductive region 1110ca may be greater than the third length l3 of the portion of the first semiconductor pattern 1110 corresponding to the third edge 1220ea of the second gate electrode 1220 in the first direction (e.g., the ±x direction). In other words, the ninth length l9 of the fifth portion 1110cab of the first conductive region 1110ca may be greater than the length l3 of the boundary between the first conductive region 1110ca and the first semiconductor region 1110s.

According to an embodiment, the tenth length l10 of the sixth portion 1110cbb of the second conductive region 1110cb may be greater than the fourth length l4 of the other portion of the first semiconductor pattern 1110 corresponding to the fourth edge 1220eb of the second gate electrode 1220 in the first direction (e.g., the ±x direction). In other words, the tenth length l10 of the sixth portion 1110cbb of the second conductive region 1110cb may be greater than the length l4 of the boundary between the second conductive region 1110cb and the first semiconductor region 1110s.

When the fourth electrode 1340 is disposed over the second gate electrode 1220 and the twenty third electrode 1010 is disposed under the second gate electrode 1220, the portion of the first semiconductor pattern 1110 corresponding to the third and fourth edges 1220ea and 1220eb of the second gate electrode 1220 may be protected by the fourth electrode 1340 and the twenty third electrode 1010. Thus, even when the display apparatus receives an impact from the outside, a crack may be prevented from occurring in the portion of the first semiconductor pattern 1110 corresponding to the third and fourth edges 1220ea and 1220eb of the second gate electrode 1220. In an embodiment, a crack may occur at a portion of the first semiconductor pattern 1110 corresponding to the ninth edge 1010ea and the tenth edge 1010eb of the twenty third electrode 1010 due to an external impact. In such an embodiment, the first semiconductor pattern 1110 includes a protrusion as shown in FIG. 22, such that the area of the first semiconductor pattern 1110 corresponding to the ninth edge 1010ea and the tenth edge 1010eb of the twenty third electrode 1010 may increase, and thus such cracking may be effectively prevented.

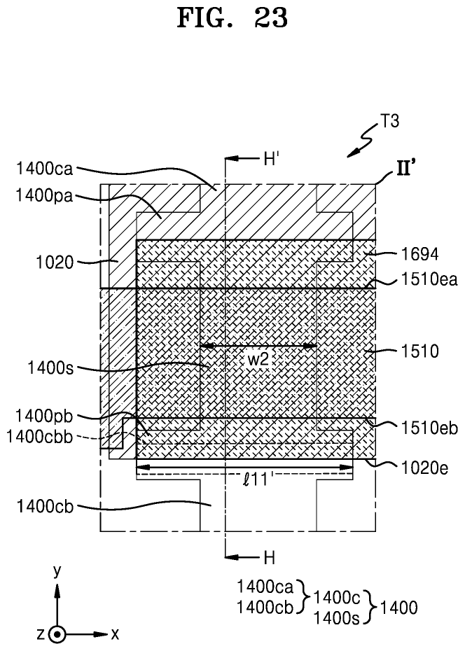

FIG. 23 is an enlarged plan view schematically illustrating a portion of FIG. 9. FIG. 23 is a modification of FIG. 20, and thus the display apparatus shown in FIG. 23 substantially the same as the display apparatus shown in FIG. 20 except for the structure of an electrode. Hereinafter, any repetitive detailed description of the same or like elements a those of FIG. 20 will be omitted, and the differences will be mainly described.

Referring to FIG. 23, an embodiment of the display apparatus may further include a twenty fourth electrode 1020. The twenty fourth electrode 1020 may at least partially overlap the fourth gate electrode 1510, the second semiconductor layer 1400, and the eighteenth electrode 1694. The twenty fourth electrode 1020 may include at least one metal selected from aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W) and copper (Cu), and may have a single-layered or multi-layered structure.

According to an embodiment, as shown in FIG. 24, the twenty fourth electrode 1020 may be interposed between the substrate 100 and the buffer layer 110.

According to an embodiment, the twenty fourth electrode 1020 may be in a state in which a constant voltage is applied thereto. The twenty fourth electrode 1020 may extend from the first conductive layer 1000 of FIG. 10 in the second direction (e.g., the ±y direction).

According to an embodiment, the twenty fourth electrode 1020 may have an edge extending in the first direction (e.g., the ±x direction) and at least partially overlapping the conductive region 1400c. In an embodiment, for example, the twenty fourth electrode 1020 may have an eleventh edge 1020e extending in the first direction (e.g., the ±x direction) and at least partially overlapping the fourth conductive region 1400cb. The eleventh edge 1020e of the twenty fourth electrode 1020 may at least partially overlap the fourth protrusion 1400pb of the fourth conductive region 1400cb.

According to an embodiment, an eleventh length l11′ of a seventh portion 1400cbb of the fourth conductive region 1400cb in the first direction (e.g., the ±x direction) may be greater than the second width w2 of the second semiconductor region 1400s in the first direction (e.g., the ±x direction). The seventh portion 1400cbb of the fourth conductive region 1400cb is a portion that overlaps the eleventh edge 1020e of the twenty fourth electrode 1020 in the fourth conductive region 1400cb. The seventh portion 1400cbb of the fourth conductive region 1400cb is a portion corresponding to the eleventh edge 1020e of the twenty fourth electrode 1020.

In an embodiment, the eighteenth electrode 1694 is disposed over the fourth gate electrode 1510 and the twenty fourth electrode 1020 is disposed under the fourth gate electrode 1510, such that the portion of the second semiconductor layer 1400 corresponding to the seventh and eighth edges 1510ea and 1510eb of the fourth gate electrode 1510 may be protected by the eighteenth electrode 1694 and the twenty fourth electrode 1020. Thus, even when the display apparatus receives an impact from the outside, a crack may be effectively prevented from occurring in the portion of the second semiconductor layer 1400 corresponding to the seventh and eighth edges 1510ea and 1510eb of the fourth gate electrode 1510. In an embodiment, a crack may occur at a portion of the second semiconductor layer 1400 corresponding to the eleventh edge 1020e of the twenty fourth electrode 1020 due to an external impact. In such an embodiment, the second semiconductor layer 1400 includes a protrusion as shown in FIG. 23, such that the area of the second semiconductor layer 1400 corresponding to the eleventh edge 1020e of the twenty fourth electrode 1020 may increase, and thus such cracking may be prevented.

FIG. 24 is a cross-sectional view of a portion of FIG. 22 and a portion of FIG. 23 taken along lines G-G′ and H-H′, respectively. The same reference numerals in FIGS. 21 and 24 denote the same elements described above, and thus any repeated detailed descriptions thereof are omitted.

Referring to FIG. 24, the twenty third electrode 1010 and the twenty fourth electrode 1020 may be interposed between the barrier layer 112 and the buffer layer 110. The twenty third electrode 1010 and the twenty fourth electrode 1020 may include at least one metal selected from aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W) and copper (Cu), and may have a single-layered or multi-layered structure.

According to an embodiment, the twenty third electrode 1010 may be in a floating state, and the twenty fourth electrode 1020 may be in a state in which a constant voltage is applied thereto.

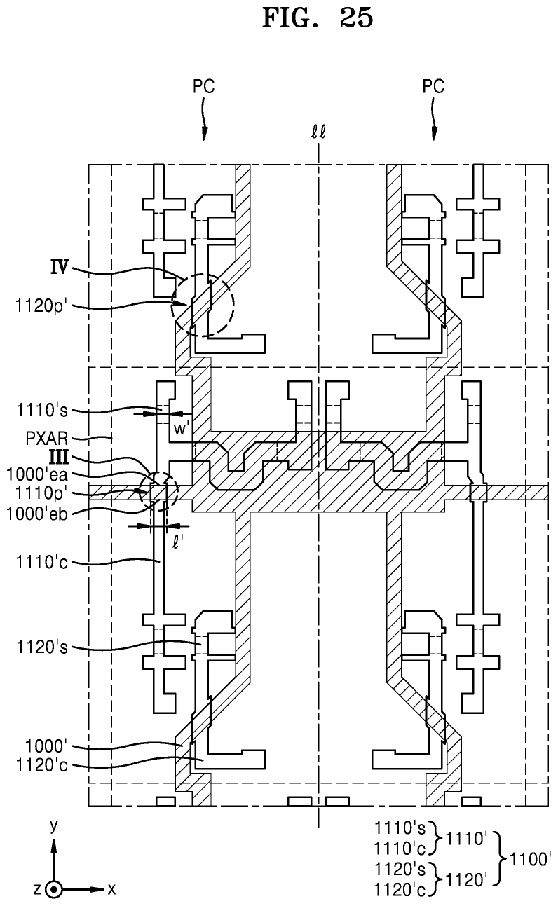

FIG. 25 is a schematic plan view of a conductive layer and a semiconductor layer included in a display apparatus according to an embodiment. In detail, FIG. 25 shows a modification of the first conductive layer 1000 of FIG. 10 and a modification of the first semiconductor layer 1100 of FIG. 11.

Referring to FIG. 25, a first conductive layer 1000′ may extend in the first direction (for example, the ±x direction) and the second direction (for example, the ±y direction). The first conductive layer 1000′ may overlap a plurality of pixel areas PXAR. The first conductive layer 1000′ may include, for example, molybdenum (Mo), aluminum (Al), copper (Cu), or titanium (Ti), and may be formed as a single layer or as a multi-layer. In an embodiment, for example, the first conductive layer 1000′ may be a single layer of Mo.

A first semiconductor layer 1100′ may be disposed on the first conductive layer 1000′. The first semiconductor layer 1100′ may include a silicon semiconductor material. In an embodiment, for example, the first semiconductor layer 1100′ may include amorphous silicon or polysilicon. In detail, the first semiconductor layer 1100′ may include polysilicon crystallized at low temperature. In some cases, ions may be implanted into at least a portion of the first semiconductor layer 1100′.

The first semiconductor layer 1100′ may include a first semiconductor pattern 1110′ and a second semiconductor pattern 1120′. The first semiconductor layer 1110′ may include a conductive region and a semiconductor region. In an embodiment, for example, the first semiconductor pattern 1110′ may include a first conductive region 1110′c and a first semiconductor region 1110's. The second semiconductor pattern 1120′ may include a second conductive region 1120′c and a second semiconductor region 1120's. The first semiconductor region 1110's corresponds to a portion where the first semiconductor pattern 1110′ overlaps the second conductive layer 1200 of FIG. 11. The second semiconductor region 1120's corresponds to a portion where the second semiconductor pattern 1120′ overlaps the second conductive layer 1200 of FIG. 11.

According to an embodiment, the conductive region of the first semiconductor layer 1100′ may include a protrusion in a portion overlapping the first conductive layer 1000′. In an embodiment, for example, as shown in a portion III, the first conductive region 1110′c of the first semiconductor pattern 1110′ may include a first protrusion 1110p′. The first protrusion 1110p′ may at least partially overlap the first conductive layer 1000′. The first protrusion 1110p′ may extend in a direction in which the first conductive layer 1000′ extends. As shown in a portion IV, the second conductive region 1120′c of the second semiconductor pattern 1120′ may include a second protrusion 1120p′. The second protrusion 1120p′ may at least partially overlap the first conductive layer 1000′. The second protrusion 1120p′ may extend in the direction in which the first conductive layer 1000′ extends.

According to an embodiment, the first electrode 1000′ may have an edge extending in the first direction (e.g., the ±x direction) and at least partially overlapping the first conductive region 1110′c. In an embodiment, for example, the first conductive layer 1000′ may have a first edge 1000′ea extending in the first direction (e.g., the ±x direction) and at least partially overlapping the first conductive region 1110′c, and a second edge 1000′eb extending in the first direction (e.g., the ±x direction) and at least partially overlapping the first conductive region 1110′c. The second edge 1000′eb of the first conductive layer 1000′ may be opposite to the first edge 1000′ea of the first conductive layer 1000′. The first edge 1000′ea and the second edge 1000′eb of the first conductive layer 1000′ may at least partially overlap the first protrusion 1110p′ of the first conductive region 1110′c.

According to an embodiment, a length t′ of the first protrusion 1110p′ in the first direction (e.g., the ±x direction) may be greater than a width w′ of the first semiconductor region 1110's in the first direction (e.g., the ±x direction).

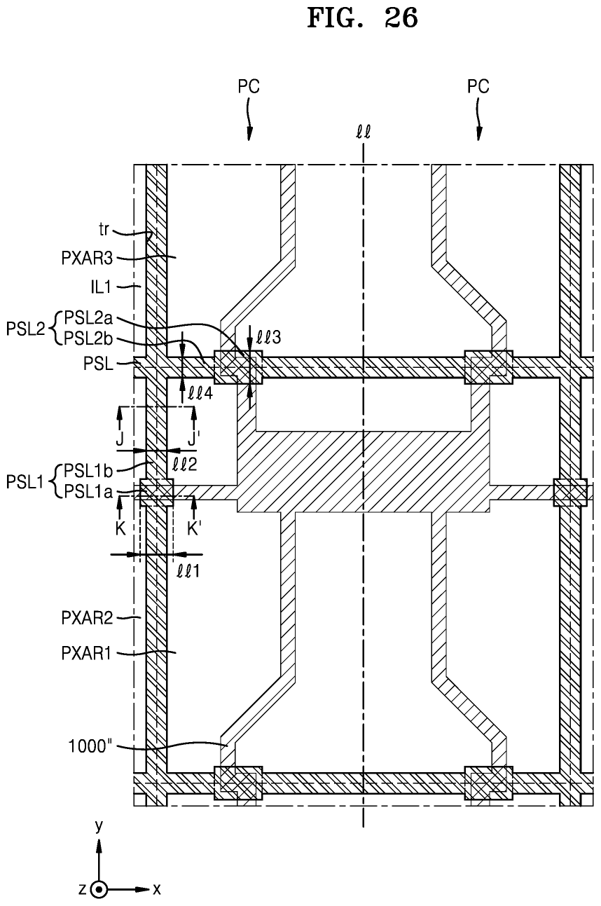

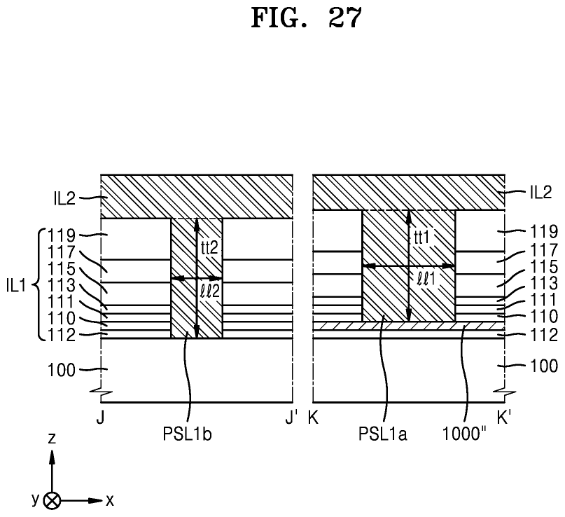

FIG. 26 is a schematic plan view of a conductive layer, an insulating layer, and a pixel separation layer included in a display apparatus according to an embodiment, and FIG. 27 is a cross-sectional view of a portion of FIG. 26 taken along lines J-J′ and K-K′. In detail, FIG. 26 illustrates modifications of the first insulating layer IL1 and the pixel separation layer PSL of FIG. 17.

Referring to FIG. 26, a first conductive layer 1000″ may extend in the first direction (for example, the ±x direction) and the second direction (for example, the ±y direction). The first conductive layer 1000″ may overlap a plurality of pixel areas PXAR. The first conductive layer 1000″ may include, for example, molybdenum (Mo), aluminum (Al), copper (Cu) or titanium (Ti), and may be formed as a single layer or as a multi-layer. In an embodiment, for example, the first conductive layer 1000″ may be a single layer of Mo. As shown in FIG. 27, the first conductive layer 1000″ may be interposed between the barrier layer 112 and the buffer layer 110.

The first insulating layer IL1 including an inorganic material may have a trench tr. The trench tr of the first insulating layer IL1 may correspond to a boundary between the pixel areas PXAR. In a plan view, the trench tr of the first insulating layer IL1 may have a lattice shape (or a mesh structure).

The pixel separation layer PSL may be disposed in the trench tr of the first insulating layer IL1. The pixel separation layer PSL may correspond to the boundary between the pixel areas PXAR. In a plan view, the pixel separation layer PSL may have a lattice shape (or a mesh structure). As the pixel separation layer PSL is disposed in the trench tr, a step of the first insulating layer IL1 caused by the trench tr may be removed or minimized.

According to an embodiment, a length of a portion of the pixel separation layer PSL overlapping the first conductive layer 1000 “may be different from that of a portion of the pixel separation layer PSL not overlapping the first conductive layer 1000”. In an embodiment, for example, a first pixel separation layer PSL1 may be buried or filled in the trench tr corresponding to a boundary between a first pixel area PXAR1 and a second pixel area PXAR2 that are adjacent to each other in a first direction (e.g., the ±x direction). The first pixel separation layer PSL1 may include a first portion PSL1a, and a second portion PSL1b adjacent to the first portion PSL1a. The first portion PSL1a of the first pixel separation layer PSL1 may at least partially overlap the first conductive layer 1000″. In an embodiment, a first length ll1 of the first portion PSL1a of the first pixel separation layer PSL1 in the first direction (e.g., the ±x direction) may be greater than a second length ll2 of the second portion PSL1b of the first pixel separation layer PSL1 in the first direction (e.g., the ±x direction).

A second pixel separation layer PSL2 may be buried in a trench tr corresponding to a boundary between the first pixel area PXAR1 and a third pixel area PXAR3 that are adjacent to each other in the second direction (e.g., the ±y direction). The second pixel separation layer PSL2 may include a third portion PSL2a, and a fourth portion PSL2b adjacent to the third portion PSL2a. The third portion PSL2a of the second pixel separation layer PSL2 may at least partially overlap the first conductive layer 1000″. In an embodiment, a third length ll3 of the third portion PSL2a of the second pixel separation layer PSL2 in the second direction (e.g., the ±y direction) may be greater than a fourth length ll4 of the fourth portion PSL2b of the second pixel separation layer PSL2 in the second direction (e.g., the ±y direction).

According to an embodiment, a thickness of the portion of the pixel separation layer PSL overlapping the first conductive layer 1000 “may be different from that of the portion of the pixel separation layer PSL not overlapping the first conductive layer 1000”. In an embodiment, for example, as shown in FIG. 27, a first thickness ll1 of the first portion PSL1a of the first pixel separation layer PSL1 in a thickness direction of the substrate 100 may be less than a second thickness ll2 of the second portion PSL1b of the first pixel separation layer PSL1 in the thickness direction of the substrate 100. The first conductive layer 1000 “may contact the first portion PSL1a of the first pixel separation layer PSL1.

In such an embodiment, the pixel separation layer PSL may include a relatively thin portion overlapping the first conductive layer 1000”. The relatively thin portion is relatively vulnerable to an external impact of the display apparatus. In an embodiment, as described above, a width (expressed as a length in a plan view) of the relatively portion is increased, such that occurrence of cracks due to an external impact may be effectively prevented.

According to an embodiment as described above, a display apparatus capable of displaying a high-resolution image while having a low defect rate due to an external impact may be realized.

The invention should not be construed as being limited to the embodiments set forth herein. Rather, these embodiments are provided so that this disclosure will be thorough and complete and will fully convey the concept of the invention to those skilled in the art.

For example, a method of manufacturing such a display apparatus also belongs to the scope of the disclosure.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display apparatus comprising:
a substrate;
a first semiconductor layer disposed on the substrate and comprising a first conductive region and a first semiconductor region which are adjacent to each other;
a first gate electrode disposed on the first semiconductor layer and at least partially overlapping the first semiconductor region; and
a first electrode extending in a first direction and having a first edge at least partially overlapping the first conductive region,
wherein a first length, in the first direction, of a first portion of the first conductive region overlapping the first edge of the first electrode is greater than a first width of the first semiconductor region in the first direction.

2. The display apparatus of claim 1, wherein
the first semiconductor layer further comprises a second conductive region,
the first semiconductor region is located between the first conductive region and the second conductive region, and
the first electrode at least partially overlaps the first gate electrode, and further comprises a second edge which extends in the first direction, at least partially overlaps the second conductive region, and is opposite to the first edge.

3. The display apparatus of claim 2, wherein a second length, in the first direction, of a second portion of the second conductive region overlapping the second edge of the first electrode is greater than the first width of the first semiconductor region in the first direction.

4. The display apparatus of claim 2, wherein
the first conductive region includes a first protrusion extending in the first direction,
the second conductive region includes a second protrusion extending in the first direction,
the first edge of the first electrode at least partially overlaps the first protrusion of the first conductive region, and
the second edge of the first electrode at least partially overlaps the second protrusion of the second conductive region.

5. The display apparatus of claim 2, further comprising:
a second electrode interposed between the substrate and the first semiconductor layer and at least partially overlapping the first electrode.

6. The display apparatus of claim 5, wherein
the first electrode is in a floating state, and
the second electrode is in a floating state or a state in which a constant voltage is applied thereto.

7. The display apparatus of claim 5, wherein
the second electrode has a third edge which extends in the first direction and at least partially overlaps at least one of the first conductive region and the second conductive region, and
a second length, in the first direction, of a second portion of the first semiconductor layer overlapping the third edge of the second electrode is greater than the first width of the first semiconductor region in the first direction.

8. The display apparatus of claim 1, further comprising:
a second semiconductor layer including a different material from the first semiconductor layer and comprising a second conductive region and a second semiconductor region which are adjacent to each other;
a second gate electrode disposed on the second semiconductor layer and at least partially overlapping the second semiconductor region; and
a second electrode extending in the first direction and having a second edge at least partially overlapping the second conductive region,
wherein a second length, in the first direction, of a second portion of the second conductive region overlapping the second edge of the second electrode is greater than a second width of the second semiconductor region in the first direction.

9. The display apparatus of claim 8, wherein
the first semiconductor layer includes a silicon semiconductor material, and
the second semiconductor layer includes an oxide semiconductor material.

10. The display apparatus of claim 8, further comprising:
a pixel circuit disposed on the substrate; and
a display element electrically connected to the pixel circuit,
wherein
the pixel circuit comprises:
a driving transistor which controls a current flowing to the display element according to a gate-source voltage;
a scan transistor which transmits a data voltage to the driving transistor in response to a scan signal; and
a compensating transistor which connects a drain of the driving transistor to a gate of the driving transistor in response to a compensation signal,
the scan transistor comprises the first gate electrode to which the scan signal is applied, and the first semiconductor layer, and
the compensating transistor comprises the second gate electrode to which the compensation signal is applied, and the second semiconductor layer.

11. The display apparatus of claim 1, wherein the first electrode is disposed in a floating state on the first gate electrode.

12. The display apparatus of claim 1, wherein
the first electrode further comprises a second edge which extends in the first direction, at least partially overlaps the first conductive region, and is opposite to the first edge, and
a second length, in the first direction, of a second portion of the first conductive region overlapping the second edge of the first electrode is substantially equal to the first length, in the first direction, of the first portion of the first conductive region.

13. The display apparatus of claim 12, wherein
the first conductive region includes a protrusion extending in the first direction, and
the first edge and the second edge of the first electrode at least partially overlap the protrusion of the first conductive region.

14. The display apparatus of claim 12, wherein the first electrode is interposed between the substrate and the first semiconductor layer, and in a state in which a constant voltage is applied thereto.

15. The display apparatus of claim 12, wherein, in a plan view, the first electrode is spaced apart from the first semiconductor region of the first semiconductor layer.

16. A display apparatus comprising:
a substrate, in which a first pixel area and a second pixel area adjacent to each other in a first direction are defined;
a conductive layer disposed on the substrate;
a first insulating layer disposed on the substrate and having a trench corresponding to a boundary between the first pixel area and the second pixel area; and
a pixel separation layer filled in the trench and including a first portion at least partially overlapping the conductive layer and a second portion adjacent to the first portion,
wherein a first length of the first portion of the pixel separation layer in the first direction is greater than a second length of the second portion of the pixel separation layer in the first direction.

17. The display apparatus of claim 16, wherein a first thickness of the first portion of the pixel separation layer in a thickness direction of the substrate is less than a second thickness of the second portion of the pixel separation layer in the thickness direction of the substrate.

18. The display apparatus of claim 16, wherein the conductive layer is interposed between the substrate and the first portion of the pixel separation layer and contacts the first portion of the pixel separation layer.

19. The display apparatus of claim 16, wherein the pixel separation layer includes a different material from the first insulating layer.

20. The display apparatus of claim 16, wherein the first insulating layer includes an inorganic material, and the pixel separation layer includes an organic material.

21. The display apparatus of claim 16, further comprising:
a semiconductor layer disposed on the first pixel area and comprising a conductive region and a semiconductor region which are adjacent to each other,
wherein
the conductive layer has a first edge extending in a second direction and at least partially overlapping the conductive region, and
a third length, in the second direction, of a first portion of the conductive region overlapping the first edge of the conductive layer is greater than a width of the semiconductor region in the second direction.

22. The display apparatus of claim 21, wherein
the conductive layer further comprises a second edge which extends in the second direction, at least partially overlaps the conductive region, and is opposite to the first edge, and
a fourth length, in the second direction, of a second portion of the conductive region overlapping the second edge of the conductive layer is substantially equal to the third length, in the second direction, of the first portion of the conductive region.

23. The display apparatus of claim 22, wherein
the conductive region comprises a protrusion extending in the second direction, and
the first edge and the second edge of the conductive layer at least partially overlap the protrusion of the conductive region.

24. The display apparatus of claim 21, wherein the conductive layer is interposed between the substrate and the semiconductor layer, and is in a state in which a constant voltage is applied thereto.

25. The display apparatus of claim 21, wherein, in a plan view, the conductive layer is spaced apart from the semiconductor region of the semiconductor layer.
